(19) United States
(12) Patent Application Publication
(10) Pub. No.: US 2025/0380560 A1
(43) Pub. Date: Dec. 11, 2025

(54) PRESSURE-SENSITIVE TRANSISTOR ELEMENT, PRESSURE-SENSITIVE TRANSISTOR DISPLAY INCLUDING THE SAME, AND TACTILE PATTERN RECOGNITION SYSTEM USING THE SAME

(71) Applicant: UIF (University Industry Foundation), Yonsei University, Seoul (KR)

(72) Inventors: Cheol Min PARK, Seoul (KR); Kyu Ho LEE, Seoul (KR); Ye Eun KIM, Seoul (KR); Woo Joong KIM, Seoul (KR)

(73) Assignee: UIF (University Industry Foundation), Yonsei University, Seoul (KR)

(21) Appl. No.: 19/227,815

(22) Filed: Jun. 4, 2025

(30) Foreign Application Priority Data
Jun. 11, 2024 (KR) 10-2024-0075800

(51) Int. Cl. H10K 10/40; G06F 3/044; H10K 10/84; H10K 10/88

(52) U.S. Cl. CPC H10K 10/40; G06F 3/0446; H10K 10/84; H10K 10/88

(57) ABSTRACT

Disclosed area a pressure-sensitive transistor device, a pressure-sensitive transistor display, and a tactile input pattern recognition system. The pressure-sensitive transistor device includes: a semiconductor layer; a block copolymer layer disposed on an upper surface of the semiconductor layer, wherein the block copolymer layer has a stack structure in which hydrophilic layers and hydrophobic layers are vertically and alternately stacked on top of each other, wherein the block copolymer layer contains cations and anions therein; an ion-gel layer disposed on an upper surface of the block copolymer layer; a source electrode and a drain electrode disposed on a lower surface of the semiconductor layer and electrically contacting the semiconductor layer, wherein the source electrode and the drain electrode area spaced apart from each other; and a gate electrode disposed on an upper surface of the ion-gel layer and in electrical and physical contact with the ion-gel layer.

### CROSS-REFERENCE TO RELATED APPLICATION

This application claims priority from Korean Patent Application No. 1-2024-0075800 filed on Jun. 11, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to a pressure-sensitive transistor device, a pressure-sensitive transistor display including the same, and a tactile input pattern recognition system using the same.

### Description of Related Art

The Artificially Intelligent (AI) human-interactive electronics facilitate the recognition of a human receivable stimulus as well as the memorization and learning from the stimulus based on neuro-inspired synaptic computing technologies. Among these, AI electronic skin (e-skin) has gained much attention owing to its potential applications in wearable, patchable, and embedded electronics, particularly for sensing and learning from stimuli such as pressure, light, temperature, chemical, and humidity. The integration of display function into AI e-skins creates new types of neuromorphic devices with the ability to visualize the stimuli-response in real-time. This capability allows users to directly observe and analyze information-processing behavior with brain-inspired computing technologies. Particularly, visualization of an artificial synapse associated with various tactile stimuli such as pressing magnitude and repetitive tapping is of great importance for real-time motion tracking, potentially offering an efficient way for a personal encryption system. Despite the importance of the development of tactile AI e-skin display systems, the integration of sensors, memory devices, and display units in a single device remains a challenge. Various tactile visual synapses have been reported, consisting of individual sensors, artificial synapses, and light emitting devices physically interconnected in some cases with microprocessor units for facile signal conversion of those from the sensor and synapse into the display. These complex and bulky systems are rarely suitable for miniaturized encryption systems due to the poor wearability of the devices on the body or machine interfaces.

### SUMMARY

The present disclosure presents a novel tactile neuromorphic display into a single device enabled by block copolymer (BCP) structural color (SC) capable of a dual output of optical and electrical signals by combining the functionality of reflective mode display with a synaptic transistor that allows for sensing, storing, learning, and visualizing the number and magnitude of external tactile stimuli. The proposed device is based on an ion-gel gated transistor with a dome-shaped gate electrode and a BCP photonic crystal (PC) consisting of periodically ordered BCP lamellae which serve as tactile-interactive color-tunable gate dielectrics. The self-assembled BCP PCs enable an electrically switchable reflective mode SC display in which the periodic lamellae of the BCP PC were tuned in size due to the gate electric field-dependent in-and-out of hydrated cations in the BCP PC/ion-gel (IG) bilayer dielectric. Concurrently, the anions in the ion-gel migrate towards the semiconductor channel under the gate field and potentially are doped within it. These phenomena allow synaptic modulation of channel conductivity. Since the SC in the BCP PC gate dielectric and synaptic feature of channel conductance share the principle of ion-migrating behavior responsive to the gate electrical field, which can also be modulated with various tactile stimuli, the channel synaptic properties triggered by the tactile stimuli are directly and simultaneously visualized in SC. Furthermore, a 4×4 array of the present tactile neuromorphic displays was fabricated to propose a novel dual personal locking device that can detect information using both wavelength and current. This innovative locking device recognizes personal touch patterns programmed in different pressing magnitudes and times, which offers a route to design an enhanced.

A purpose of the present disclosure is to develop a new type of transistor device capable of providing a more improved interactive experience to a user by improving limitations found in previous technologies. Thus, when a specific pressure and voltage are applied thereto, the color change and the electrical conductivity change may be more precisely adjusted, so that the user may more clearly recognize the response of the device thereto. In addition, this technology provides the possibility that the new type of transistor device is integrated into various types of electronic devices and interfaces, and may be particularly useful in security systems or personal identification systems. For example, in a door lock or secure login system, this technology may help learn and recognize an individual's unique pressure and touch patterns.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a pressure-sensitive transistor device comprising: a semiconductor layer; a block copolymer layer disposed on an upper surface of the semiconductor layer, wherein the block copolymer layer has a stack structure in which hydrophilic layers and hydrophobic layers are vertically and alternately stacked on top of each other, wherein the block copolymer layer contains cations and anions therein; an ion-gel layer disposed on an upper surface of the block copolymer layer; a source electrode and a drain electrode disposed on a lower surface of the semiconductor layer and electrically contacting the semiconductor layer, wherein the source electrode and the drain electrode area spaced apart from each other; and a gate electrode disposed on an upper surface of the ion-gel layer and in electrical and physical contact with the ion-gel layer.

In accordance with some embodiments of the pressure-sensitive transistor device, each of the hydrophobic layers includes polystyrene (PS).

In accordance with some embodiments of the pressure-sensitive transistor device, each of the hydrophilic layer includes quaternized poly(2-vinylpyridine) (QP2VP).

In accordance with some embodiments of the pressure-sensitive transistor device, the cation is a lithium (Li) cation, or the anion is a trifluoromethanesulfonyl imide (TFSI) anion.

In accordance with some embodiments of the pressure-sensitive transistor device, the semiconductor layer includes poly(3-hexylthiophene-2,5-diyl) (P3HT).

In accordance with some embodiments of the pressure-sensitive transistor device, the ion-gel layer includes a polymer selected from polyvinylidene fluoride (PVDF), trifluoroethylene (TrFE), and chlorofluoroethylene (CFE), wherein the ion-gel layer contains the cation and the anion therein.

In accordance with some embodiments of the pressure-sensitive transistor device, each of the source electrode, the drain electrode and the gate electrode includes gold (Au).

In accordance with some embodiments of the pressure-sensitive transistor device, the gate electrode has a dome shape convex toward the ion-gel layer.

In accordance with some embodiments of the pressure-sensitive transistor device, the gate electrode is constructed to transfer a vertical pressure to the ion-gel layer and to the block copolymer layer.

In accordance with some embodiments of the pressure-sensitive transistor device, the pressure-sensitive transistor device is configured such that when both a pressure and a voltage are simultaneously applied to the gate electrode, a structural color of the block copolymer layer changes.

In accordance with some embodiments of the pressure-sensitive transistor device, the pressure-sensitive transistor device is configured such that when a pressure is applied to the gate electrode or a voltage is applied to the gate electrode, an electrical conductivity between the source electrode and the drain electrode through the semiconductor layer changes.

A second aspect of the present disclosure provides a pressure-sensitive transistor display comprising: a plurality of pressure-sensitive transistor devices arranged in an array, wherein the plurality of pressure-sensitive transistor devices have pressure receiving surfaces, wherein the have pressure receiving surfaces are arranged so as to be aligned with each other, wherein each of at least some of the plurality of pressure-sensitive transistor devices includes the pressure-sensitive transistor device as described above.

In accordance with some embodiments of the pressure-sensitive transistor display, wherein the pressure-sensitive transistor device is configured such that when both a pressure and a voltage are simultaneously applied to the gate electrode, a structural color of the block copolymer layer changes.

A third aspect of the present disclosure provides a tactile input pattern recognition system comprising: the pressure-sensitive transistor display as described above; and a computing means configured to: receive an electrical signal and a color signal from each of the pressure-sensitive transistor devices included in the pressure-sensitive transistor display, wherein the electrical signal and the color signal are based on an actual input pattern to the pressure-sensitive transistor display; and derive a similarity between the actual input pattern and a predetermined input pattern, based on the received electrical signal and color signal.

In accordance with some embodiments of the tactile input pattern recognition system, the computation means is pre-trained in a deep learning manner.

The development of tactile stimuli interactive display with a self-learning function in a single device is highly desired and holds promise for potential applications such as intelligent electronic and photonic skin and human-machine interfaces. In the present disclosure, the inventors of the present disclosure report a tactile neuromorphic display enabled by block copolymer (BCP) structural color (SC) capable of sensing, storing, learning, and visualizing various external tactile stimuli in a single device architecture where the functionality of reflective mode display is combined with a synaptic transistor. The proposed device is based on an ion-gel gated transistor with a dome-shaped elastomeric gate electrode and a BCP photonic crystal with periodically ordered lamellae which serve as tactile-interactive color-tunable gate dielectrics. The SC of BCP is readily switched due to the migration of cations in an ion-gel stacked on a BCP photonic crystal under an electric field which can be modulated with various tactile stimuli. At the same time, the synaptic conductance behavior occurs in the semiconducting channel of the ion-gel transistor with the tactile stimuli, allowing for direct visualization of the synaptic characteristics in SC. Furthermore, the inventors of the present disclosure fabricated a 4×4 array of tactile neuromorphic displays to propose a novel dual personal locking device that can detect information using optical wavelength as well as electrical current. The new locks are prohibited from being accessed if the pressing magnitude and time are different, even if the path of the pattern is identified.

The effect of the present disclosure is that the color and conductivity may be adjusted in real time according to a user's input, thereby greatly improving the interactivity of the interface. This function helps the user to more intuitively manipulate the device by providing color changes in response to various pressures on the touch screen of the smart device, and are useful for visually presenting a complex concept to visual learners in an educational environment. In addition, a customized security system is implemented using a user's unique pressure pattern and a touch pattern, thereby implying the possibility of providing a high level of security and personalization in the personal authentication process.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

The patent or application file contains a least one drawing executed in color. Copies of this patent or patent application publication with color drawing(s) will be provided by the Office upon request and payment of the necessary fee.

FIG. 1A Schematic illustration of the biological tactile perception system and the artificial tactile neuromorphic structural color display. The process of sensing external pressure and transmitting information through electrical signals and structural color changes was simulated like biological systems.

FIG. 1B Cross-sectional SEM image of TNSCD. This shows the results of observing the configuration of the layers, the shape of the nanostructure, and the interface characteristics between materials using a scanning electron microscope (SEM).

FIG. 1C 1D SAXS plot of azimuthal scattering intensity versus scattering vector q of the 200 wt % Li+TFSI-concentration with respect to the PVDF-TrFE-CFE polymer. This is a graph showing the effect of ion doping on polymer internal nanostructures through small angle X-ray scattering (SAXS) analysis.

FIG. 1D Photograph of TNSCD after the application of pressure on elastomeric top gate electrode. The actual picture shows the structural color of the TNSCD surface changing according to the pressure application.

FIG. 1E Optical microscopic image of the interdigitated source and drain electrode pattern. This image shows a structure in which the source and drain electrodes intersect each other, and the white dotted circle represents the area (pressed area) to which pressure is applied.

FIG. 2A A left diagram shows a schematic illustration of 2-terminal BCP SC reflective-mode display; and a right diagram shows a schematic illustration of working mechanism of 2-terminal BCP SC reflective-mode display: Li⁺ and TFSI⁻ ion migration in (i) reverse-biased (+2V) state and (ii) forward-biased (−2V) state during the application of electric field.

FIG. 2B Cyclic voltammetry of the 2-terminal BCP SC reflective-mode display with two Au electrodes. It represents the electrical switching characteristics of the device.

FIG. 2C Photographs of E-switched BCP SC display as a function of operation time at the electric field of ±2V. It visually shows the structural color change according to the switching process.

FIG. 2D Plots of CIE coordinates corresponding to the results from FIG. 2C. It quantitatively represents the color coordinate shift according to the structural color change.

FIG. 2E Repeatability test of 2-terminal BCP SC reflective-mode display with the applied voltage of −2V for 240 s and +2V for 240 s in one cycle. This is data that evaluates the durability and reliability of electrical switching.

FIG. 3A Schematic illustration of the constant pressure mode of the TNSCD device. VG pulses are applied on the gate electrode under constant pressure.

FIG. 3B IDS-VG transfer characteristics under a pressure of 15 kPa. The inset images display reversible transition of structural color from red to green through a VG sweep ranging from 5V to −5V.

FIG. 3C Long-term potentiation (LTP) and Long-Term Depression (LTD) plots of PSC as a function of the number of VG pulses of ±1V, ±1.5V, and ±2V for td=100 ms, Δt=2 s at constant pressure of 15 kPa. The inset images show photographs of SC after 100 consecutive potentiating pulses were applied.

FIG. 3D Plots of PSC response and photographs of SC with respect to the different number of electrical pulses (ranging from 5 to 100) at constant pressure of 15 kPa. The upper images display photographs of SC after 5, 10, 15, 20, 25, 50, and 100 gate pulses were applied.

FIG. 3E Time-resolved measurement of wavelength after the administration of 100 gate pulses of VG=−2V, for td=100 ms, Δt=2 s. The upper images show photographs of SC captured at intervals of 60 seconds.

FIG. 3F Sequential LTP/LTD transition by different number of gate pulses ranging from 10 to 100 pulses; VG=±2V, for td=100 ms, Δt=2 s.

FIG. 3G Cycling LTP/LTD transition during continuous 4000 VG pulses.

FIG. 4A Pressure synaptic characteristics of tactile neuromorphic structural color display. Schematic illustration of constant VG mode of the TNSCD. VG pulses are constantly applied while applying pressure pulses.

FIG. 4B Plots of contact area between the electrode and the ion-gel with respect to the magnitude of pressure.

FIG. 4C Plots of PSC response by different magnitudes of pressure pulse at VG=−2V and VD=−0.1V.

FIG. 4D Plots of PSC response with respect to different numbers of pressure pulses ranging from 5 to 30 under the pressing magnitude of 11.08 kPa and the constant gate voltage of VG=−2V.

FIG. 4E LTP and LTD of the PSC as a function of the number of VG pulses of ±2V for 100 ms at 5 different pressure levels ranging from 2.35 to 21.97 kPa. The right inset images show the SC after 100 potentiating VG pulses are applied.

FIG. 4F Area and wavelength plots extracted from the right inset images of FIG. 4E.

FIG. 4G Plots of PSC response with respect to the time pressure applied ranging from 10 to 100 s under continuous VG pulses (−2V, 0.5 Hz) and constant pressure of 15.78 kPa. The right inset images display SC after the different number of voltage pulses are applied.

FIG. 4H Area and wavelength plots extracted from the right inset images of FIG. 4G.

FIG. 4I Plot of CIE coordinates corresponding to the results of FIG. 4F and FIG. 4H.

FIG. 5A Personal dual locking device with TNSCD: Schematic illustration of the 4×4 device array and concept of locking system using pressure magnitude and pressing time.

FIG. 5B Schematic illustration of access denied person 1 with the correct time and wrong pressure, access denied person 2 with wrong time and correct pressure, and access granted case about correct time and pressure.

FIG. 5C Photographs of personal locking device array according to the condition of FIG. 5B.

FIG. 5D Schematic illustration for selecting a sample from the population. Each sample has 10 people. The right side represents a pixel dataset including current, color, and pressure area based on the pressure pattern of ‘person 3’.

FIG. 5E Dataset Augmentation with noise factor (NF)=50%.

FIG. 5F Single-layer neural network simulation with test dataset at the case of ‘access granted’.

FIG. 5G Recognition accuracies for the four different conditions with conductance, color, and area during 30 learning epochs. Inset: the confusion matrices between output and target values for a classification test of the 10 persons.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in the present disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. In the context of the present disclosure, the term “about” may mean about ±1%, about ±2%, about ±3%, about ±4%, about ±5%, about ±6%, about ±7%, about ±8%, about ±9%, or about ±10% of a value stated herein.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

A first aspect of the present disclosure provides a pressure-sensitive transistor device comprising: a semiconductor layer; a block copolymer layer disposed on an upper surface of the semiconductor layer, wherein the block copolymer layer has a stack structure in which hydrophilic layers and hydrophobic layers are vertically and alternately stacked on top of each other, wherein the block copolymer layer contains cations and anions therein; an ion-gel layer disposed on an upper surface of the block copolymer layer; a source electrode and a drain electrode disposed on a lower surface of the semiconductor layer and electrically contacting the semiconductor layer, wherein the source electrode and the drain electrode area spaced apart from each other; and a gate electrode disposed on an upper surface of the ion-gel layer and in electrical and physical contact with the ion-gel layer.

The role of the semiconductor layer acts as a key medium for conducting electrons or holes. This layer determines the basic electrical characteristics of the semiconductor element and provides a path through which charge carriers may migrate between the source electrode and the drain electrode. In particular, this semiconductor layer plays an important role in processing electrical signals and controlling the operating state of the device. As long as the above-described role is performed, the material of the semiconductor layer is not particularly limited. In an embodiment, the semiconductor layer may include poly(3-hexylthiophene-2,5-diyl) (P3HT). Other non-limiting examples thereof may include polythiophene, polyaniline, polypyrrole, polyvinylthiophene, poly(3,4-ethylenedioxythiophene) (PEDOT), polyacetylene, polyphenylenevinylene, polyfluorene, poly(naphthalenevinylene), polycarbazole, polysilane, polyazothiophene, poly(3-butylthiophene)), poly(phenylthiophene), polyimide, polysiloxane, polyphenylene, Poly(pyridine), polynaphthalene, and polybenzothiadiazole.

In the context of the present disclosure, the meaning of the hydrophobic layer and the hydrophilic layer means a layer having a property of rejecting water and a layer having a property of attracting water, respectively. Each of these layers has a specific chemical property and structural arrangement, which determines the manner in which each layer interacts with water. In addition, in the context of the present disclosure, the meaning of the term that the hydrophobic layers and the hydrophilic layers are vertically and alternately stacked on top of each other indicates that these two types of layers are vertically alternately arranged with each other to form a structural complex, and this structure is designed to optimize the characteristics of each of the layers and supplement the characteristics thereof with each other as necessary. This alternating stacking structure plays an important role in allowing the functional layers to enhance the mutual action or to express new properties.

In an embodiment, the hydrophobic layer may include polystyrene (PS). There are several advantages when polystyrene (PS) is used for the hydrophobic layer. First of all, polystyrene has excellent chemical stability and low moisture absorption, and thus maintains structural integrity even in a humid environment. In addition, polystyrene is economical and easy to process, and thus is suitable for mass production. This material also exhibits high light transmittance, which may help improve optical properties in structural color displays. Using polystyrene, the hydrophobic layer may function as an optically activated layer while improving resistance to external environmental factors.

In an embodiment, the hydrophilic layer may include quaternized poly(2-vinylpyridine) (QP2VP). The term “quaternized” usually refers to a state in which a methyl group or other alkyl group is attached to an organic compound containing nitrogen, and through this process, a cationic polymer is generated. QP2VP is a structure in which a quaternary ammonium group is introduced into a chain of Poly(2-vinylpyridine), and this configuration is characterized by very strong hydrophilicity and excellent ion exchange ability. Using QP2VP, the hydrophilic layer exhibits excellent water absorption ability and can quickly swell by reacting with water. This provides the advantage of inducing a more sensitive and faster color change in the display device.

The role of the block copolymer layer acts as an intermediate medium for storing therein and migrating ions, thereby adjusting the electrical characteristics of the device. Since this layer contains cations and anions, ions migrate therein according to a change in voltage or pressure, thereby changing the conductivity of the semiconductor layer and consequently causing a color change. This structure plays an important role, especially in the pressure-sensitive transistor, and can greatly improve sensitivity and reactivity.

The block copolymer layer having the vertical alternate arrangement of the hydrophilic layers and the hydrophobic layers as described above may have a structural color under a specific condition. In the context of the present disclosure, the meaning of the structural color is a color generated by a microstructure inside a material, and the color is based on an optical phenomenon such as interference, diffraction, or scattering of light. The hydrophilic and hydrophobic layers in the aligned state in the block copolymer layer may strengthen or weaken the wavelength of certain light, resulting in color change. This structural color plays an important role in improving the visual characteristics of the device and is particularly useful in user interface or display technology.

The role of the cations and anions is to dynamically adjust the conductivity of the transistor and the structural color of the block copolymer layer via the migration under the electric field. The cations migrate in the direction of the electric field, while the anions migrate in the opposite direction thereto. When a voltage is applied to the gate electrode, the voltage induces ions to the semiconductor layer through the ion-gel layer. In this process, the cation migrates in the direction of the electric field and the anion migrates in the opposite direction to the direction of the electric field, and this migration changes the charge density of the semiconductor layer to control the conductivity. In addition, the migration of these ions plays an important role in controlling the structural color of the block copolymer layer. When a voltage is applied to the gate electrode, ions inside the block copolymer layer migrate in response to an electrical stimulus, and in this process, the lamellar structure of the hydrophilic layer and the hydrophobic layer swells or contracts. Such a physical change changes an interference pattern of light, thereby causing a shift of a structural color.

As long as the above-described function is performed, the types of the cations and the anions are not particularly limited.

In one example, the cation may be a lithium (Li) cation. Other non-limiting examples of the cations may include sodium (Na), potassium (K), calcium (Ca), magnesium (Mg), ammonium (NH₄), aluminum (Al), barium (Ba), strontium (Sr), copper (Cu), zinc (Zn), nickel (Ni), cobalt (Co), manganese (Mn), silver (Ag), iron (Fe), chromium (Cr), cadmium (Cd), mercury (Hg), cesium (Cs), or titanium (Ti) cations.

In an embodiment, the anion may be a trifluoromethanesulfonyl imide (TFSI) anion. Other non-limiting examples of the anions may include perchlorate (ClO4), tetrafluoroborate (BF₄), hexafluorophosphate (PF₆), tetrafluorotartrate (C₄O₄), hexafluorosilicate (SiF₆), bis(trifluoromethanesulfonyl)imide ((N(SO₂CF₃)₂), nitrate (NO₃), sulfate (SO₄), acetate (CH₃COO), phthalate (C₈H₄O₄), citric acid (C₆H₅O₇), malate (C₄H₄O₅), salicylate (C₇H₅O₃), benzoate (C₇H₅O₂), acetate (C₂H₃O₂), glycolate (C₂H₃O₃), lactate (C₃H₅O₃), malonic acid (C₃H₂O₄), aniline acid (C₆H₇NO₂), or pyridine (Py) anions.

The role of the ion-gel layer is to form an electrical interface between the gate electrode and the block copolymer layer to control the operation of the device according to electrical and physical signals applied from the outside. The ion-gel layer has high ion conductivity and reacts sensitively to electric field changes occurring in the gate electrode. As long as the above-described function is performed, the material of the ion-gel layer is not particularly limited. In an embodiment, the ion-gel layer may include a polymer including polyvinylidene fluoride (PVDF), trifluoroethylene (TrFE), or chlorofluoroethylene (CFE). In an embodiment, the ion-gel layer may include a polymer including polyvinylidene fluoride (PVDF), trifluoroethylene (TrFE), and chlorofluoroethylene (CFE).

In one embodiment, the ion-gel layer may contain the positive and negative ions that is, cations and anions therein. The cation and anion may mean a cation and an anion contained in the above-described block copolymer layer. Accordingly, the ion-gel layer provides a place where ions in the block copolymer layer can migrate and be stored, thereby dynamically adjusting the conductivity of the semiconductor layer. In addition, the ion-gel layer plays an important role in causing a change in structural color in response to a change in the concentration of ions in the block copolymer layer. For example, when a voltage is applied to the gate electrode, ions migrating through the ion-gel layer change the ion concentration between the hydrophilic and hydrophobic layers of the block copolymer layer to induce swelling or contraction thereof. This physical change adjusts the interference and scattering properties of light, thus contributing to the adjustment of structural colors to allow the color to vary depending on the viewing angle.

The function of the source electrode and the drain electrode is to provide an electrical path along which the charge carriers may migrate through the semiconductor layer. These electrodes allow electrons or holes to migrate through the semiconductor layer to generate or sense electrical signals. The role of the gate electrode is to adjust the electrical characteristics of the semiconductor layer through the ion-gel layer. The gate electrode adjusts the conductivity of the device by changing the charge density of the semiconductor layer by applying a voltage. In addition, it plays an important role in physically sensing pressure and converting the sensed pressure into an electrical signal, thereby enabling color change or conductivity change due to the pressure.

As long as the above-described function is performed, that is, as long as the material has conductivity, the material of each of the source, drain, and the gate electrodes is not particularly limited. In an embodiment, the source electrode, the drain electrode, or the gate electrode may include gold (Au). Other non-limiting examples of the material thereof may include silver (Ag), copper (Cu), aluminum (Al), titanium (Ti), nickel (Ni), palladium (Pd), platinum (Pt), chromium (Cr), stainless steel, zinc (Zn), tantalum (Ta), molybdenum (Mo), wolfram (W), manganese (Mn), lithium (Li), magnesium (Mg), beryllium (Be), cadmium (Cd), lead (Pb), indium (In), etc. Each of these materials has unique electrical properties and is suitable for application in various electronic, photoelectronic, and chemical environments. The advantages using gold (Au) are its excellent electrical conductivity and chemical stability. Since gold is very resistant to oxidation and corrosion, the risk of damage or performance degradation due to environmental factors is low. These characteristics greatly contribute to extending the life of the electrode and maintaining consistent performance in the long term.

In accordance with some embodiments of the pressure-sensitive transistor device, the gate electrode has a dome shape convex toward the ion-gel layer. In accordance with some embodiments of the pressure-sensitive transistor device, the gate electrode is constructed to transfer a vertical pressure to the ion-gel layer and to the block copolymer layer. In an embodiment, a portion of the gate electrode contacting the ion-gel layer may have a dome shape. Such a dome shape is very suitable for inducing a change in the structural color by dispersing the pressure over a larger area when the pressure is applied thereto and effectively transferring the pressure to the ion-gel layer and the block copolymer layer. This allows the structural color change to be adjusted more sensitively and precisely in response to physical pressure.

In accordance with some embodiments of the pressure-sensitive transistor device, the pressure-sensitive transistor device may be configured such that when both a pressure and a voltage are simultaneously applied to the gate electrode, a structural color of the block copolymer layer changes. In accordance with some embodiments of the pressure-sensitive transistor device, the pressure-sensitive transistor device may be configured such that when a pressure is applied to the gate electrode or a voltage is applied to the gate electrode, an electrical conductivity between the source electrode and the drain electrode through the semiconductor layer changes.

A second aspect of the present disclosure provides a pressure-sensitive transistor display comprising: a plurality of pressure-sensitive transistor devices arranged in an array, wherein the plurality of pressure-sensitive transistor devices have pressure receiving surfaces, wherein the have pressure receiving surfaces are arranged so as to be aligned with each other. In one embodiment, each of at least some of the plurality of pressure-sensitive transistor devices includes the pressure-sensitive transistor device as described above.

As described above, the meaning of the pressure-sensitive transistor device refers to a device that senses an electrical signal and a physical pressure and converts the sensed electrical signal and physical pressure into a color change and a conductive change. Thid device may play an important role in various application fields such as electronic displays, sensors, and interface technologies. In this regard, the meaning of the pressure receiving surface means an interface or surface that directly receives the physical pressure and transmits the physical pressure to the pressure-sensitive transistor device. This pressure receiving surface receives the pressure from a user's touch, environmental pressure, or other physical manipulation. The meaning of the pressure receiving surfaces being aligned with each other indicates that the pressure receiving surfaces of the transistor devices arranged in the array are coplanar with each other or are aligned with each other in a line or according to a specific shape, so that consistent pressure may be applied thereto and the entire display or system may operate in the synchronized manner. In this way, a more precise and efficient response may be obtained through the interaction between the devices. As the pressure-receiving surfaces are aligned with each other, the consistency and precision of responses occurring throughout the display are improved. For example, when a user presses a particular portion of the display, transistor devices adjacent to the pressed portion may response to the pressure in a similar manner as the manner in which the transistor devices in the pressed portion response thereto, thereby producing a uniform visual output or functional response.

In one embodiment, the plurality of pressure-sensitive transistor devices may be aligned in an array. In the context of the present disclosure, the meaning of an array refers to a set in which components are arranged in a certain pattern or order. This arrangement is widely used in data processing, imaging, display technology, and various sensor applications, and is designed so that the components may perform the same function or process different data independently. As the components are arranged in the array, the transistor devices may operate independently of and simultaneously with each other, which greatly improves the performance and efficiency of the entire display device. Array configuration is particularly important in pixel-based display technology, thereby allowing each pixel to sense or respond individually.

A third aspect of the present disclosure provides a tactile input pattern recognition system comprising: the pressure-sensitive transistor display as described above; and a computing means configured to: receive an electrical signal and a color signal from each of the pressure-sensitive transistor devices included in the pressure-sensitive transistor display, wherein the electrical signal and the color signal are based on an actual input pattern to the pressure-sensitive transistor display; and derive a similarity between the actual input pattern and a predetermined input pattern, based on the received electrical signal and color signal. In an embodiment, the pressure-sensitive transistor display may be the pressure-sensitive transistor display according to the above-described embodiment of the present disclosure.

As described above, the role of the pressure-sensitive transistor display is to convert physical input from a user into electrical and visual signals. The individual transistor devices of the pressure-sensitive transistor display response to the pressure such that the conductivity and color thereof vary. The change in the conductivity and color is transmitted to the data processing system. This greatly improves the interactivity of the user interface. Since the devices respond differently depending on the intensity and position of the pressure, this response information is important to accurately grasp the user's input pattern.

In addition, the computing means may be configured to: receive an electrical signal and a color signal from each of the pressure-sensitive transistor devices included in the pressure-sensitive transistor display, wherein the electrical signal and the color signal are based on an actual input pattern to the pressure-sensitive transistor display; and derive a similarity between the actual input pattern and a predetermined input pattern, based on the received electrical signal and color signal. This computing means processes and determines each of the inputs from the devices to, for example, recognize a unique input pattern of the user in the security system, or take necessary measures to execute a specific command in the user interface. In this process, the computing means may use an algorithm that may quickly and accurately analyze complex data patterns.

As long as the computing means performs the above-described function, an inherent algorithm, circuit design, or learning method employed for the computing means to perform such a function is not particularly limited. In an embodiment, the computing means may be pre-trained through deep learning. In the context of the present disclosure, the meaning of deep learning is a form of machine learning that learns complex patterns from a large amount of data through an artificial neural network, and automatically performs prediction or decision via the learning result. Deep learning technology exerts strong performance in various fields such as image recognition, voice recognition, and natural language processing, and may be used as a core element of the computing means that recognizes and processes the complex input patterns.

Hereinafter, examples of the present disclosure will be described. However, the examples as described below are only some implementations of the present disclosure, and the scope of the present disclosure is not limited to the following examples.

### Results

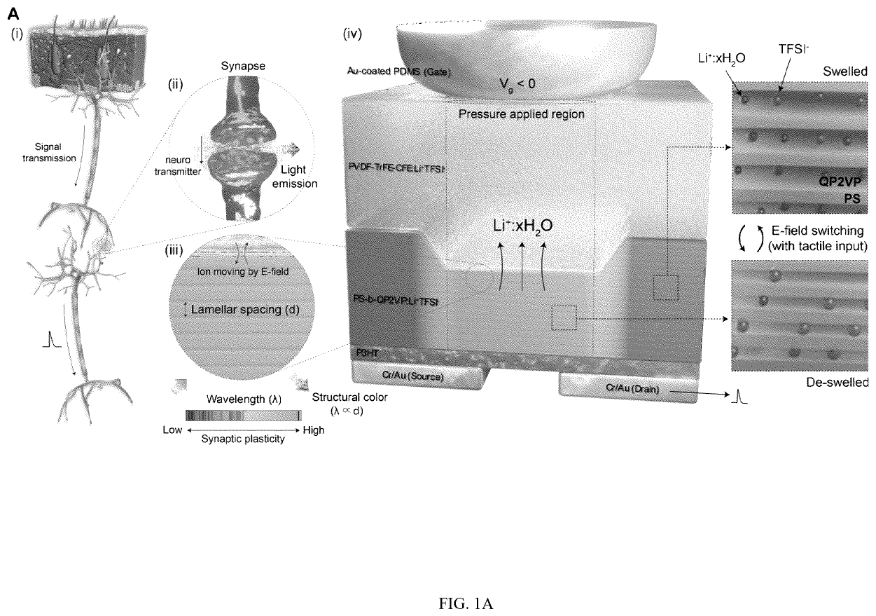

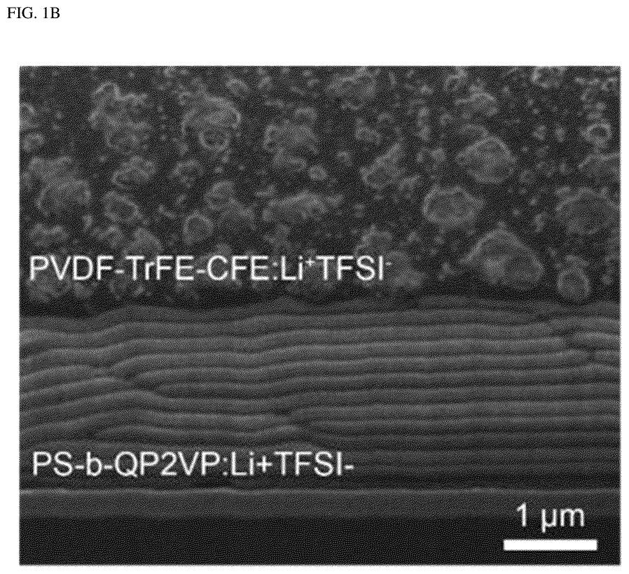

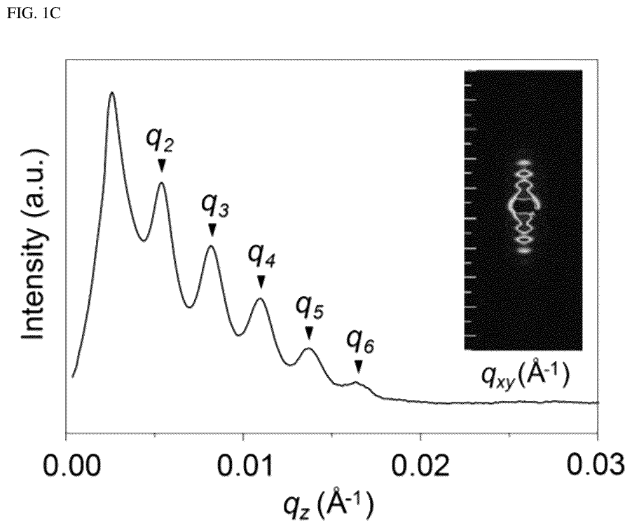

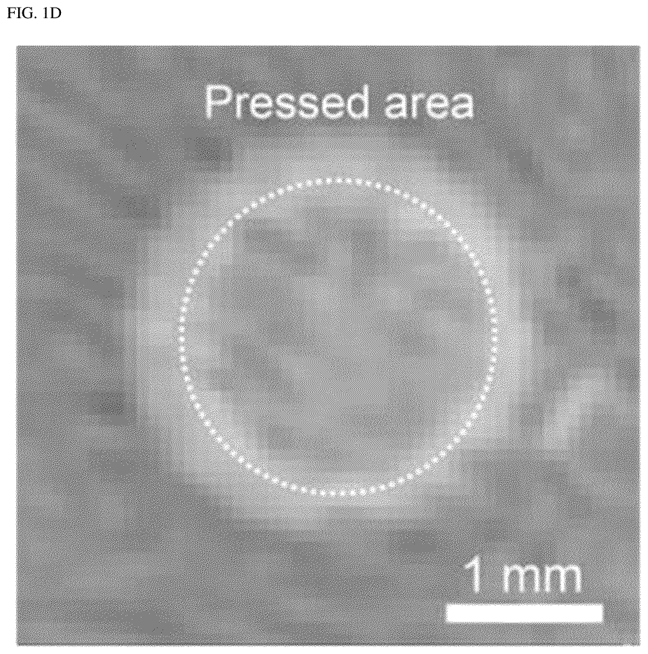

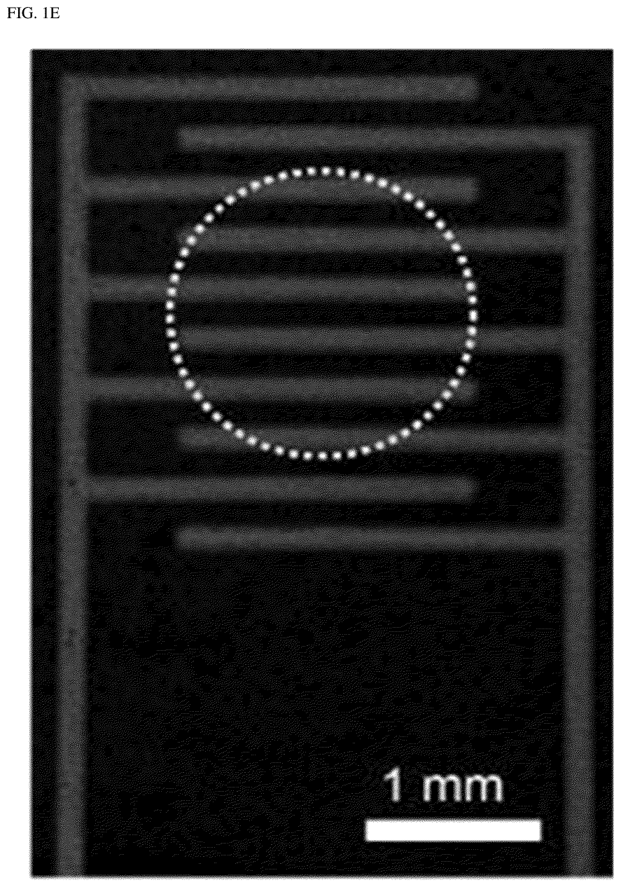

The present tactile neuromorphic structural color display (TNSCD) has a top-gate bottom contact ion-gel gated transistor (IGT) structure that consists of a interdigitated Au source(S)/drain (D) electrode, a poly(3-hexylthiophene-2,5-diyl) (P3HT) semiconductor, a poly(styrene-block-quaternized 2vinyl pyridine) (PS-b-QP2VP) BCP and ion gel, which is made by spin coating of blend solution of poly(vinylidene fluoride-trifluoroethylene-chlorofluoroethylene) (PVDF-TrFE-CFE) and hygroscopic lithium bis(trifluoromethanesulfonyl) imide (Li⁺TFSI⁻), bilayer gate dielectric, and a dome-shaped polydimethylsiloxane (PDMS) gate electrode coated with gold, as schematically shown in FIG. 1A to FIG. 1E. The present TNSCD can imitate and display a biological signal transmission process. The tactile information is transmitted from a tactile sensory receptor to a primary somatosensory cortex through a neural network that is connected by biological synapses between pre- and post-neurons, as schematically shown in FIG. 1A-(i).

In the biological signal transmission system, external stimuli applied on the skin are converted into an electrical signal in the presynaptic neuron as a form of the action potential, which makes a secretion of neurotransmitters in between the synapse and converted back into an electrical signal in the postsynaptic neuron as shown in FIG. 1A-(ii). Similarly, in the TNSCD, a sensory receptor is recognized by a pressure-sensitive top-gate electrode. The contact area with the lower BCP PC/IG bilayer dielectric can be controlled according to the magnitude of the external pressure, as shown in FIG. 1A-(iv). TFSI-ions that exist in the BCP PC/IG bilayer move by the gate voltage and form an electrical double layer at an interface with the P3HT semiconductor and accumulate excess hole carriers in the semiconductor layer through ion-doping into the semiconductor, which corresponds to the signal transmitting procedure through neurotransmitters in the biological sensory synapse. In other words, the conductance of the P3HT channel can be switched and varied according to the history of the magnitude and the number of applied pressures, as well as the electrical voltage pulses to the gate electrode. The variable contact area depends on the magnitude of tactile pressure, which subsequently determines the degree of change in channel conductance (G) between S and D electrodes, thus allowing for changes in the drain current (IDS). In this perspective, the G in the TNSCD is a continuously variable function that is determined by the tactile pressure through the pressure-dependent ion movement, which can potentially mimic diverse biological tactile synaptic functions.

In addition to imitating the biological synaptic function of the tactile nervous system, the TNSCD allows visualization of tactile and electrical stimuli through the reflective display by the degree of swelling of BCP PC, which is simultaneously regulated by ion migration, as shown in FIG. 1A-(iii). The wavelength and color-switching behavior of SC mirrors the synaptic plasticity characteristics of the TNSCD. In the present previous papers, the inventors of the present disclosure demonstrated a full-color reflective display based on electric-field switchable BCP SC. The inventors of the present disclosure employed poly (styrene-block-2vinyl pyridine) (PS-b-P2VP) BCP, which has periodically ordered alternating in-plane lamellae of the PS and P2VP domains. After quarternizing the amine group in the pyridine ring of the P2VP domain using a solution mixture of 1-bromoethane (BE) and 1,4-dibromobutane (DBB), quaternary ammonium compounds in the quaternized P2VP (QP2VP) chains allowed facile access to the ionic components, and enhanced absorption and interaction with water molecules. Because of this interaction, the hydrated Li⁺ ions moving in response to the electric field can penetrate and swell the QP2VP layer, thus resulting in red-shifted SC upon a biased field. By switching the polarity of the electric field, the BCP SC could also be blue-shifted to demonstrate a full-visible range SC display.

In the present disclosure, the inventors of the present disclosure utilized the BCP/IG bilayer as tactile-interactive color tunable gate dielectrics for an ion-gel based synaptic transistor, allowing in situ visualization of synaptic characteristics in response to tactile stimuli, as illustrated in FIG. 1A-(iv). The switchable BCP SC is driven by swelling and deswelling of the periodic QP2VP lamellae, enabled by ion movement under tactile pressure-associated electric fields. Therefore, it is imperative to select a material system capable of controlling the SC of BCP display. The seamless interfaces between BCP and IG layers were achieved through a direct spin-coating method. This bilayer configuration ensures facile ionic migration across both layers. Notably, this system, predicated on structural changes through ion injection and-release, exhibits greater reliability during repeated cycling operations compared to conventional self-emitting light-emitting diodes (LEDs).

Prior to the innovation of the inventors of the present disclosure, the visualization of synaptic characteristics—such as PSC (Post-synaptic current), LTP/LTD (Long-term potentiation/depression), and PPF (Paired-pulse facilitation)—was largely limited to configurations like light-emitting transistors or LEDs linked to transistors. In these traditional setups, variations in synaptic features were often represented by the intensity of light emission at a singular color or wavelength. However, this method can be somewhat subjective, as light intensity is relative and may be perceived differently by different individuals, requiring an accessory photodetector to quantify the stimuli-responsive light intensity. In contrast to conventional setups based on light-emitting displays, the present TNSCD is advantageous since BCP SCs with full visible wavelengths can be utilized, thereby offering a more immediate and universally understandable representation of synaptic behavior. Consequently, these characteristics allow for an innovative single-integrated TNSCD to simultaneously detect, learn, and synchronously display various tactile inputs as described below.

A cross-sectional scanning electron microscope (SEM) image of fabricated TNSCD was taken, exhibiting a self-assembled lamellar structure of BCP PC with a thickness of approximately 1.5 μm in FIG. 1B, which corresponds to the initial structural color (SC) of initial red. The in-plane lamellar periodicity of the initial red BCP PC/IG bilayer and neat BCP film was measured by 2D small-angle X-ray scattering (SAXS) in transmission mode (FIG. 1C). Multiple reflections of the neat BCP film appeared, corresponding to the 1st-order, 2nd-order, 3rd-order and 4th-order reflections at scattering vectors (qn) of 0.0086 Å⁻, 0.0171 Å⁻¹, 0.0259 Å⁻¹, 0.0343 Å⁻¹, respectively, with qₙ/q₁ ratios of approximately 1, 2, 3 and 4. The calculated periodicity of the neat BCP film (2π/q₁) before IG deposition was approximately 73.5 nm with both PS and QP2VP domains of approximately 37 nm in width due to the symmetric composition of PS and QP2VP in the BCP. Upon employment of the IG with 200 wt. % Li⁺TFSI⁻ with respect to PVDF-TrFE-CFE, the first-order reflection was rarely detected because of parasitic scattering near the incident beam at low q regimes. The scattering vectors of the relative peak positions of the high-order reflections corresponding to the first peak positions (qₙ/q₁) of 2, 3, 4, 5, 6 were 0.0054 Å⁻¹, 0.0082 Å⁻¹, 0.0109 Å⁻¹, 0.0137 Å⁻¹, 0.0164 Å⁻¹, respectively. Based on these values, the periodicity of the initial red SC was calculated to be approximately 228.5 nm with PS and QP2VP/Li TFSI of approximately 37 nm and 192 nm, respectively. FIG. 1D depicts a photograph of the TNSCD with the initially red-colored SC, which shows a green-colored SC within the pressure-applied region (inside of the white dotted circle). FIG. 1E displays an optical microscopic image of the present electrode pattern, featuring a channel with a length of 120 μm and a width of 1.4 cm. Notably, a distinctive color gradient is observable at the circumference of a circular area. This gradient's origin can be attributed to the lateral diffusion of hydrated Li⁺ ions occurring within the block copolymer lamellae.

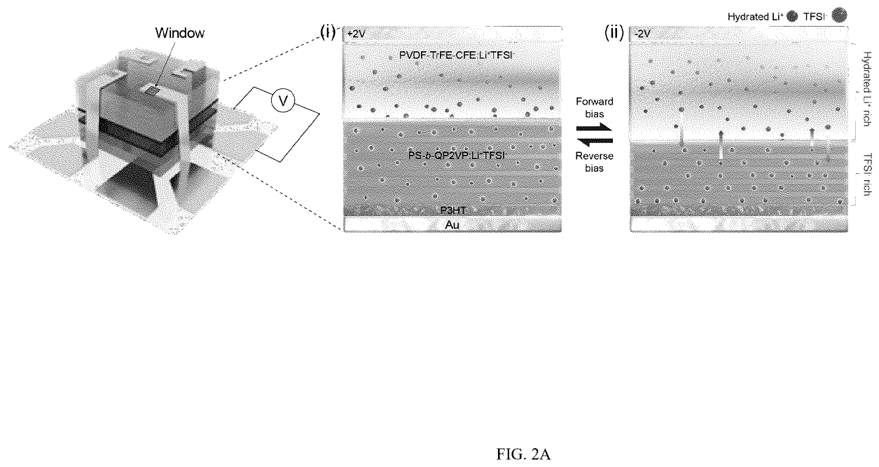

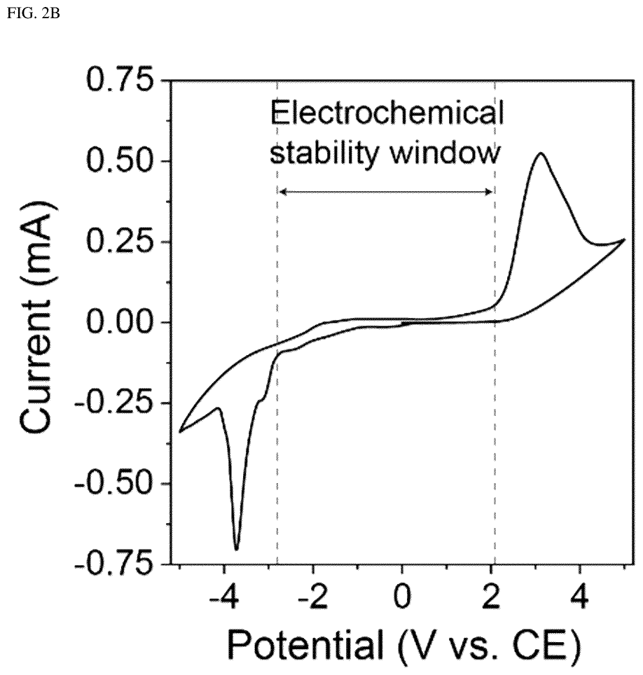

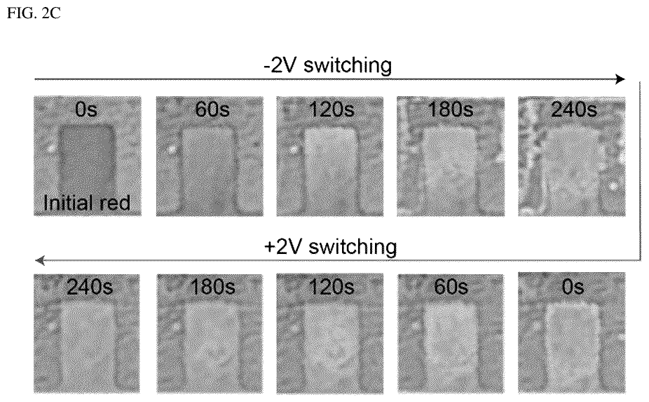

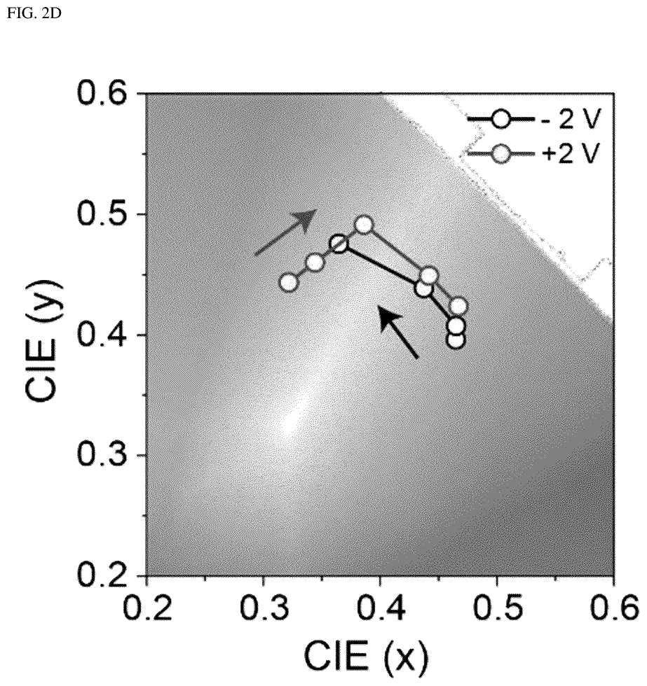

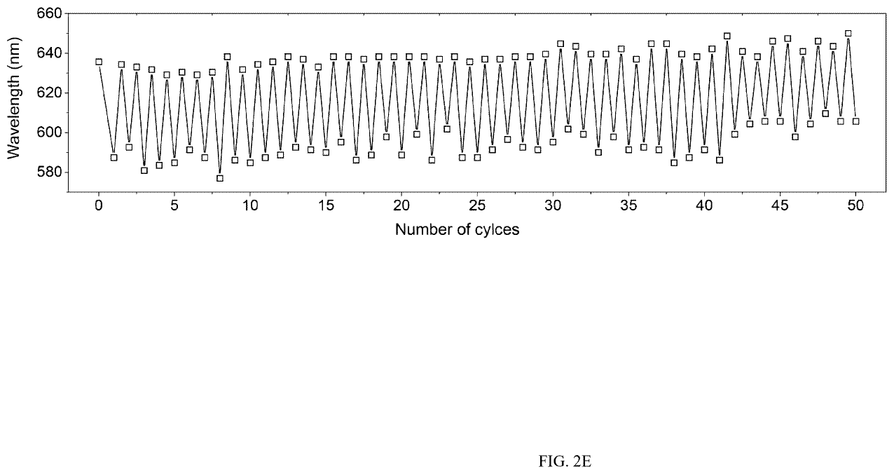

To analyze properties of electrically switchable BCP SC, the inventors of the present disclosure designed a 2-terminal BCP SC reflective-mode display consisting of an Au top electrode, a BCP PC/IG bilayer, P3HT semiconductor, and an Au/Cr bottom electrode. The SC of a BCP PC/IG bilayer responsive to the E-field between two Au electrodes was directly visualized through an open window of the top Au electrode with an area of 1×2 mm², as indicated by the dotted black box in FIG. 2A. The previous work of the inventor of the present disclosure demonstrated that the Li⁺ ion has the first and second hydration shells by water molecules with coordination numbers of 4.27 and 9.34, respectively, responsible for the hygroscopic properties. When negative voltage was applied on top Au electrode, hydrated Li⁺ ion moved toward the PVDF-TrFE-CFE ion gel reservoir with water molecules, thus de-swelling PS-b-QP2VP BCP PC, subsequently changing BCP structural color from initial red to blue-shifted one. After releasing voltage or applying a positive voltage on top Au electrode, the blue-shifted structural color reverted to its initial red. This change is attributed to the electrostatic diffusion or E-field responsive movement of hydrated Li⁺ ions, which makes the QP2VP domain swollen. In addition, the electrochemical stability of the Au electrodes associated with hydrated Li⁺ ions are examined by cyclovoltammetry (CV), and the results are shown in FIG. 2C. The Au electrodes exhibited electrochemical stability and suppressed oxidation reaction kinetics within −3V to 2V range, in which reduction and oxidation of the hydrated Li⁺ ions rarely occur.

The SC of a BCP PC/IG display under an E-field was monitored with a continuously applied DC voltage of 2V in RH (relative humidity) 30%, as shown in the series of photographs taken at various observation times in FIG. 2D. E-switching of the display in the low 30% RH resulted in an SC change from red to green even after an observation time of 240 s, mainly due to the low mobility of the hydrated Li⁺ ions in the BCP PC at low humidity. After applying a reverse voltage of 2V, the SC of BCP PC changed from green to initial red. At RH 50%, the BCP SC display exhibited an SC change from initial red to green and even blue under the ±2V E-field with observation time of 240 s. It is expected that high humidity increases the number of hydrated Li+ ions and accelerates the movement of hydrated Li⁺ ions under an E-field, offering full-colored operation in visible range.

The E-switching behavior of the BCP SC display was analyzed using the CIE 1931 color coordinates of the International Commission on Illumination, known as Commission Internationale de l'Eclairage (CIE); the coordinates were extracted from the photographs in FIG. 2D, and the results are shown in FIG. 2E. The photographs were taken at 60 s observation intervals at RH 30% with up to 240 s of −2V applied voltage followed by 240 s of 2V and the corresponding CIE values were plotted in the 2D CIE graph in FIG. 2E. The present E-switching BCP SC display exhibited reliable red-to-green SC change at RH 30% over multiple cycles of more than 50 times, as shown in FIG. 2E. The wavelength of the BCP SC display was calculated from the (x,y) color coordinates extracted from the CIE chromaticity diagram, as further detailed in the Materials and Methods section. A forward bias of −2V exerted on the top electrode resulted in a red-to-green shift of the SC of the display, and the reverse bias of 2V allowed the SC to return to the initial state of red.

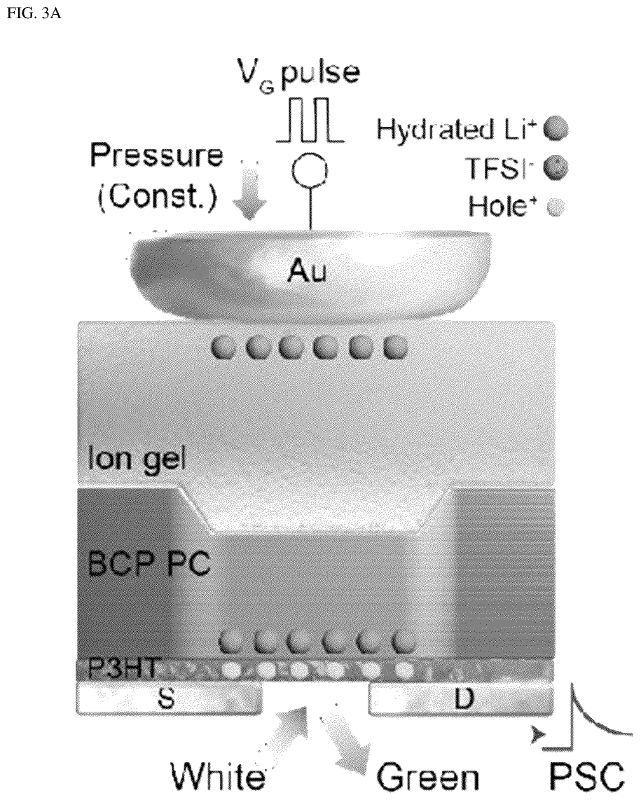

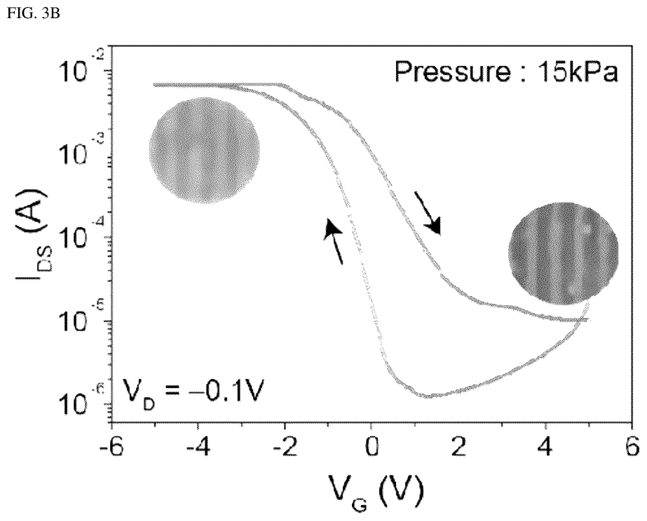

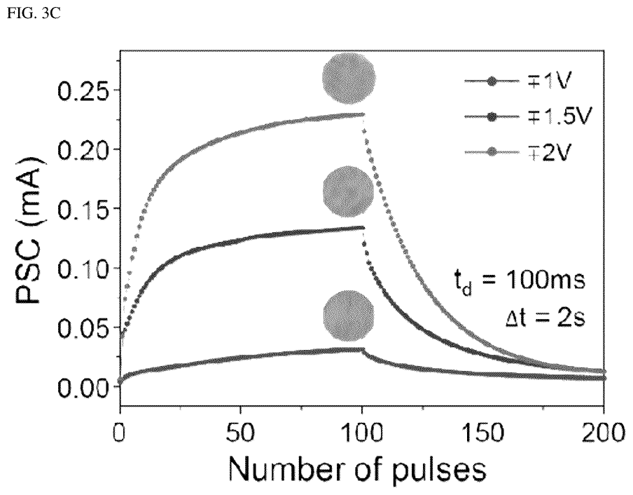

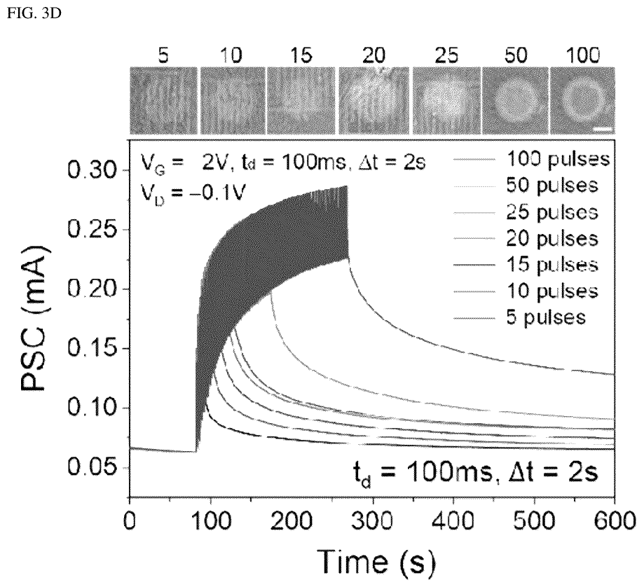

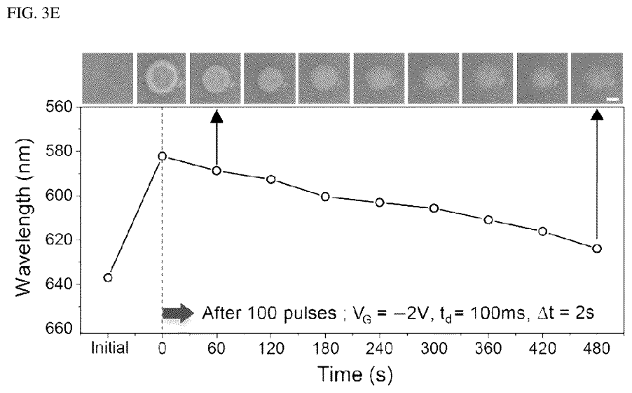

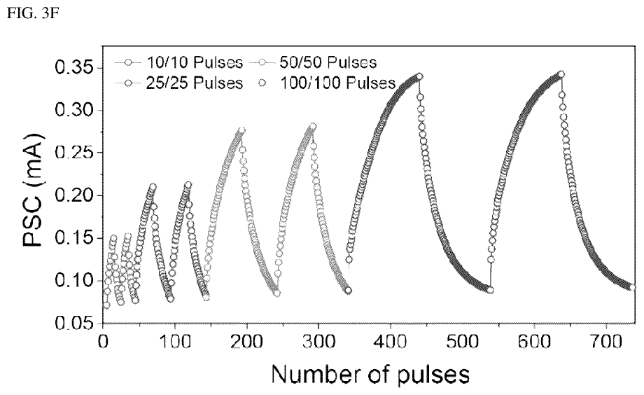

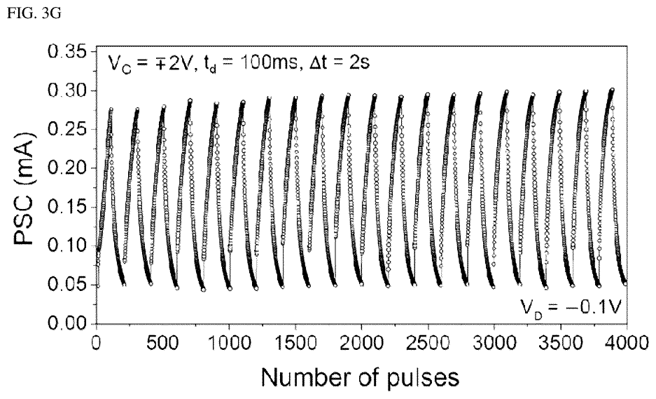

For reliable device operation, the nonvolatile electrical synaptic characteristics of the TNSCD were examined as a function of the gate voltage (V_{G}) at a given pressure under a fixed contact area (i.e., constant pressure mode). The result is shown in FIG. 3A to FIG. 3G. FIG. 3A shows the schematic illustration of the constant pressure operation of TNSCD. Under constant pressure of approximately 15 kPa, gate voltage pulses are applied, which induce ion movement in the BCP PC/IG bilayer. This results in post-synaptic current (PSC) changes and an accompanying shift in structural color. FIG. 3B shows the electrical switching characteristics of the TNSCD and the inset photographs display corresponding SCs while sweeping gate voltages. A p-type hysteresis transfer curve of I_{DS} was observed when the gate voltage (V_{G}) was swept from +5V to −5V in DC mode at a fixed pressure of 15 kPa with V_{D}=−0.1V. Two distinct ON and OFF states with ON/OFF ratio of approximately 10⁴ were observed, which occurred due to the movement of Li⁺ and TFSI⁻ ions to form an electrical double layer (EDL) at the interface of P3HT and BCP PC, and the TFSI⁻ ion (de)doping to the P3HT semiconductor layer for (low)high conductance state. The channel conductance G of the P3HT semiconductor represents the synaptic weight (w), determining the PSC at the post-neuron flow between the S and D electrodes. In addition, hydrated Li⁺ cations that was inside the QP2VP layer of BCP PC initially move toward top gate and de-swell BCP layer, inducing blue-shifted (green) SC, which is continuously switchable by gate voltage sweep to different polarity. Even after the gate voltage is removed, the drain-current exhibited slow-decaying retention property over a period of 1000 s. This is because the concentrated ions adjacent to the top-gate electrode and semiconductor by electric field slowly diffuse to a low-concentrated region driven by chemical energy gradient.

Similar to a biological synapse, the TNSCD showed interval time (Δt)-dependent facilitation behavior, called paired-pulse facilitation (PPF), where the magnitude and duration of V_{G} were −1V and 5 ms, respectively. The PPF curve was fitted using PPF=C₁·exp(−Δt/τ1)+C₂·exp(−ΔAt/τ2)+C₀. The three extracted parameters τ1=12 ms, τ2=122 ms, and C₀=101% were close to those of the biological synapse (τ1=40 ms, τ2=300 ms, and C₀=100%). Furthermore, the gradual long-term potentiation and depression (LTP/LTD) characteristics were examined, depending on the continuous input pulse trains with specific pulse duration (t_{d}), which are essential for synaptic operations in neuromorphic computing technologies as shown in FIG. 3C. One hundred discrete conduction states were achieved with maximum dynamic range of 18.8 by series of 100 presynaptic pulses (V_{G}=±1 V, ±1.5 V, and ±2 V; t_{d}=100 ms; Δt=2 s) in both the potentiation and depression processes. In addition, under 100 potentiating electrical pulses, the SC of the BCP PC changed to orange-red at 1V, orange at 1.5V, and green at 2V, showing the voltage-magnitude color dependence. FIG. 3D shows the PSC responses and corresponding SC of potentiation by V_{G} pulses (magnitude=−2V; t_{d}=100 ms; Δt=2 s) under a constant V_{D} of −0.1V. The TNSCD was triggered by various numbers of successive presynaptic voltage pulses (5, 10, 15, 20, 25, 50, 100) at a fixed pressure of 15 kPa applied at a dome-shaped pressure-sensitive gate electrode (i.e., fixed contact-area). The PSC level increased with increasing number of presynaptic pulses and then saturated, mimicking the analog weight update function of the biological synapse. As the number of pulses increased to 100 times, the SC of the pressure-applied region gradually blue-shifted from initial red to green. This phenomenon occurs due to the correlation between the number of electrical pulses applied (representing a cumulative increase in electrical power) and the resulting greater extent of ion movement. The retention property of SC in TNSCD was examined after applying 100 potentiating presynaptic pulses (V_{G}=−2 V, V_{D}=−0.1 V; t_{d}=100 ms; Δt=2 s) and the results are shown in FIG. 3E.

Following the removal of gate voltages, the SC of TNSCD was monitored and captured at every 60-second. The upper images, captured at 60-second intervals, distinctly showed that the gradual shift of SC from green to red. The exact wavelengths of SC were calculated by the CIE coordinates extracted from the images and were plotted as a function of time (see materials and method section). This gradual change of SC in TNSCD over time originated from the diffusion process of ions in BCP/IG bilayer. The hydrated lithium ions that had been moved to the ion gel reservoir by potentiating electrical pulses gradually moved back to the BCP layer to swell the BCP PC and made the SC redshifted over time. Notably, the timescale of SC transition corresponds closely to the drain current's behavior as around 500 seconds for fully bringing back to original state under identical conditions (100 pulses, as shown in FIG. 3D and FIG. 3E). This similarity implies that the underlying mechanism for both the electrical synaptic characteristics and the retention properties of the SC is rooted in ion diffusion driven by ion concentration gradients with time. In addition, the BCP SC retention properties with different magnitudes of V_{G} pulses (V_{G}=−0.5, −1, −1.5, and −2 V) were also shown, which clearly showed that the retention property of SC also had voltage-magnitude dependence similar to that of drain current. This unique property of the present TNSCD owing to the synchronized changes of SC and drain current enables to visualize doping and de-doping amount of TFSI anion into the P3HT semiconductor.

For practical usage of TNSCD device, the stability of synaptic performance against electrical stress should be secured. FIG. 3F shows LTP/D characteristics across four pairs of cycles, each having two cycles with different number of gate pulses, ranging from 10 to 100, where V_{G} was fixed at ±2 V; t_{d}=100 ms; Δt=2 s. The LTP/D curves for all cases consistently exhibit similar off-current with different dynamic ranges of 2.04, 2.69, 3.46, and 3.88, respectively. This shows that the present synaptic device can maintain its reliable conductance modulation characteristics regardless of the number of gate pulses. Furthermore, the inventors of the present disclosure monitored the LTP/D characteristics over 20 cycles corresponding 4000 pulses while applying consecutive 100 potentiating and 100 depressing pulses to gate electrode for a cycle (V_{g}=±2 V; t_{d}=100 ms; Δt=2 s). As shown in FIG. 3G, the present TNSCD exhibits robust LTP/D characteristics against electrical stresses.

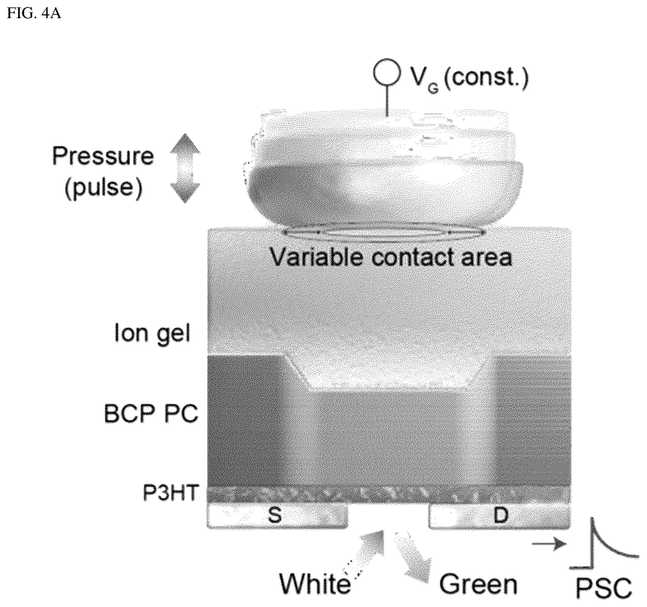

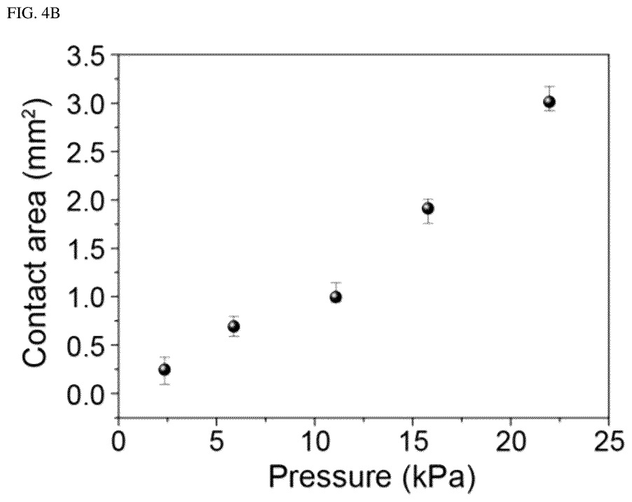

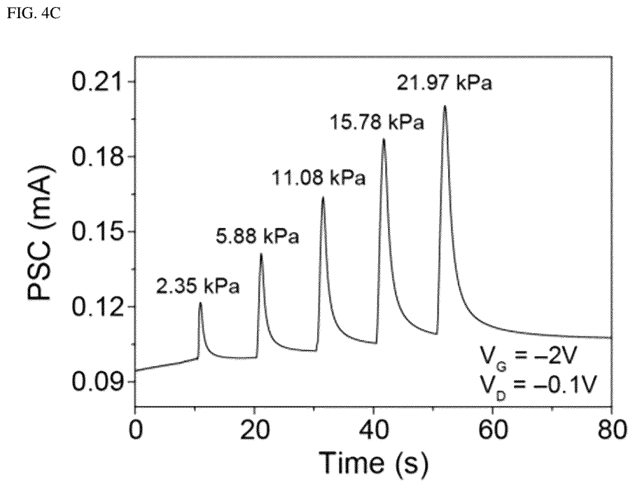

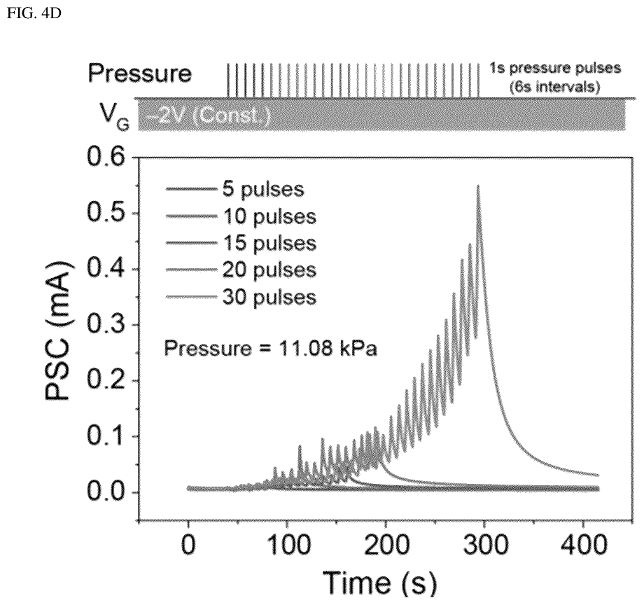

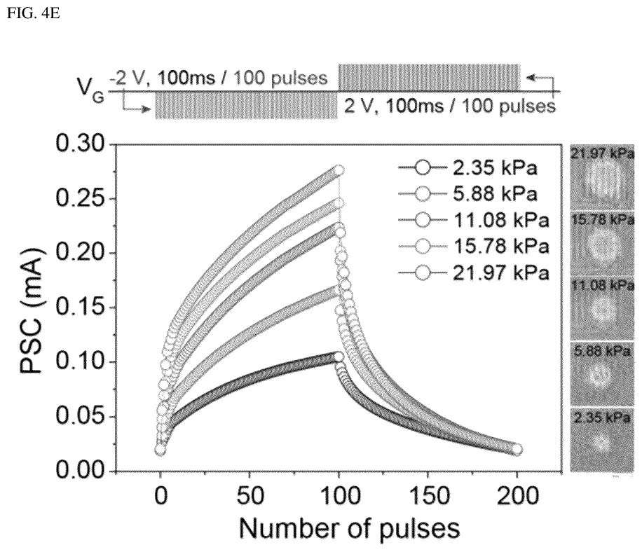

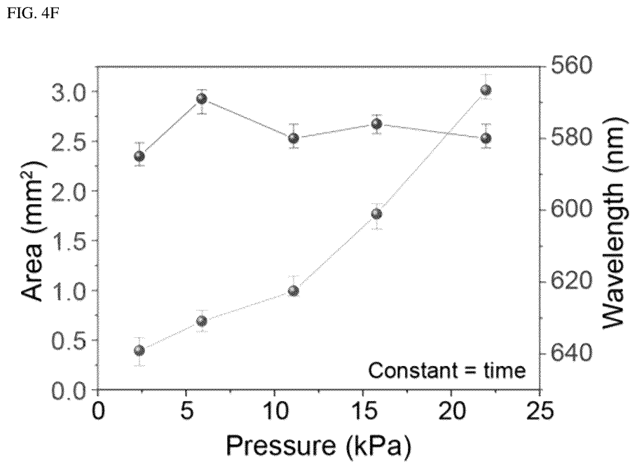

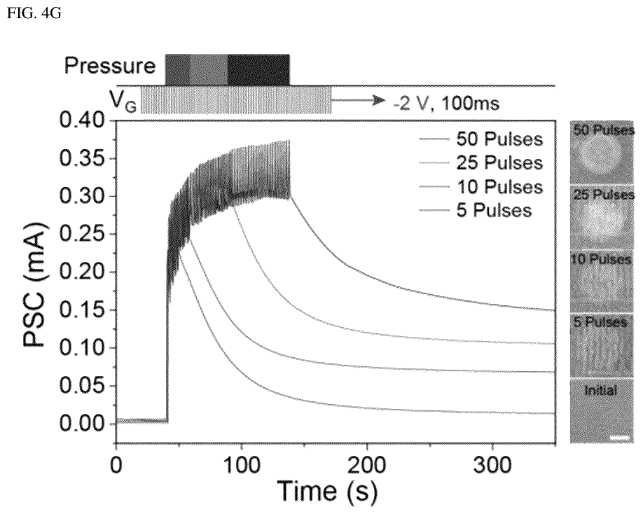

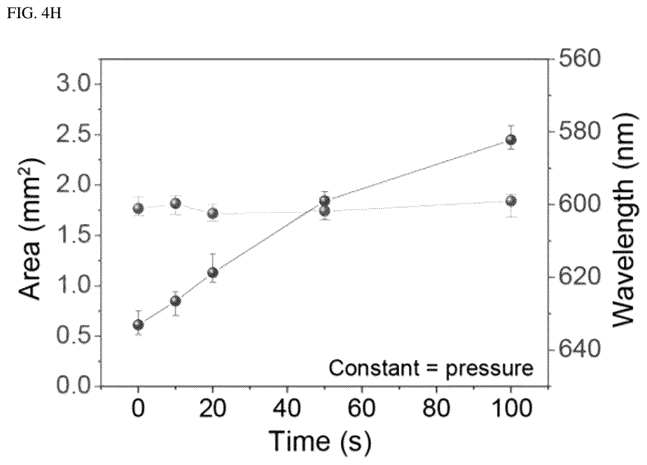

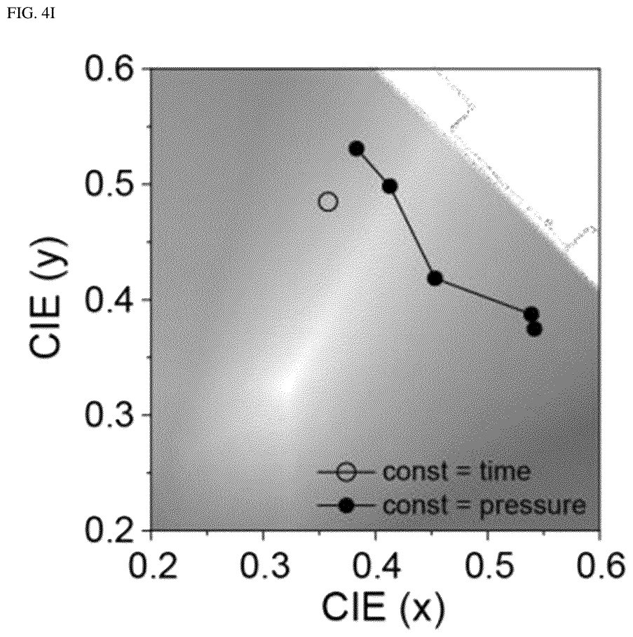

Furthermore, the pressure-stimulated synaptic performance of TNSCD was examined by pressure pulse trains at a given gate voltage (i.e. constant gate field mode). In the TNSCD architecture, as shown in FIG. 4A, the Au-coated dome-shaped top-gate plays simultaneous roles as both the tactile receptor and the axon of the pre-neuron, which can modulate the number of ions stimulated by pressure. The electric signals by ion-movement were transferred to the synaptic cleft (i.e., interface between BCP PC/IG bilayer and semiconductor layer), resulting in the flow of a PSC corresponding to a certain synaptic weight from the source to the drain electrode. Similar to a biological synapse where synaptic plasticity is strengthened from repetitive and persistent stimuli between pre- and postsynaptic neuron, when the pressure pulses were applied with a higher amplitude or more frequent cycles in the TNSCD, the more number of ions move to form electrical double layer at the interface of gate dielectric and semiconductor layer or doped to semiconductor, increasing synaptic weight (w). Therefore, TNSCD can mimic various tactile synaptic functions by adjusting the number/magnitude of pressure-pulses, and polarity of the V_{G} pulses.

The ion-movement depends on the contact area of the dome-shaped gate electrode on the BCP PC/IG gate dielectric bilayer, which varies according to the pressure, as plotted in FIG. 4B. The pressure-sensitive synaptic performance of the TNSCD device was examined with various magnitudes of pressure pulses under a given gate field. To apply the pressure pulses, an Au-coated dome-shaped electrode was repeatedly pressed and released to the TNSCD device under a constant gate voltage. FIG. 4C illustrates distinct postsynaptic current responses resulting from varying magnitudes of pressure pulses ranging from 2.35 to 21.97 kPa, each lasting for 1 second and separated by intervals of approximately 10 seconds. Concurrently, consistent values of V_{G} (gate voltage) and V_{D} (drain voltage) were sustained at V_{G}=−2V and V_{D}=−0.1V. In the presence of applied pressure pulses, a consequential adjustment of the contact area and channel width resulted in different magnitude of post-synaptic currents. Based on the time-resolved results, including the peak and decay (i.e., retention) current in FIG. 4C, the excitatory postsynaptic current (EPSC) gradually increased, proportional to the magnitude of the pressure spike and then remained even after the pressure inputs were turned off, which is like the behavior of LTP in biological synapses.

The pressure spike number-dependent synaptic plasticity (SNDP) by increasing the number of pressure pulses (5, 10, 15, 20, 30) was examined while maintaining the pressure magnitude, pressure pulse width, pressure pulse intervals, and V_{G} magnitude as 11.08 kPa, 1 s, 4 s and −2 V respectively. As shown in FIG. 4D, the values of EPSC increased as the number of pressure pulses increased from 5 to 30. In addition, the inventors of the present disclosure examined the spike-amplitude-dependent plasticity (SADP) by increasing the amplitude of the pressure (2.35, 5.88, 11.08, 15.78, 21.97 kPa at V_{G}=−1 V) with the same pulse interval of 10 s for 5 times.

FIG. 4E shows the long-term potentiation (LTP) and Long-term depression (LTD) characteristics measured using 100 repetitive electrical pulses at V_{G}=±2 V during potentiation and depression under constant pressure of 2.35, 5.88, 11.08, 15.78, 21.97 kPa. The time width and interval of each electric spike were 100 ms and 2 s, respectively. The PSC level at the same number of pulses increased with the applied pressure magnitude due to the larger area of electric-field applied region, thus resulting in larger channel width. With an escalation in pressure and a concurrent rise in the magnitude of the postsynaptic current, the spatial region within which Li⁺ ions, carrying opposite charges, traverse also expands. Consequently, as the BCP PC undergoes de-swelling, the expanse accommodating the manifestation of blue-shifted SC also enlarges, as shown in right inset images of FIG. 4E. Since the magnitude of the electric field is consistent across all scenarios and the SC has voltage-magnitude dependency, the wavelengths extracted from the images remain uniform across these cases, which are also plotted in FIG. 4F.

Moreover, pressure-pulse number dependent synaptic plasticity was also examined, and the results are shown in FIG. 4G. The magnitude of pressure was fixed as 21.97 kPa while applying the voltage pulses of V_{G}=−2V and 0.5 Hz. While 0.5 Hz of electrical pulse is being applied to the gate electrode, an electrical pulse is applied only when pressure is applied, and thus the number of electrical pulses applied is determined by the duration of application of pressure. For instance, as shown in FIG. 4G, if the pressing time increases from 10, 20, 50, and 100 seconds, 5, 10, 25, and 50 electrical pulses are applied, respectively. As shown in the inset images of FIG. 4G, the area where the structural color changed remained constant due to the same magnitude of pressure (15 kPa) for each instance. However, with an increased number of pressure pulses, the structural color exhibits a more pronounced blue-shifted color. The area and the wavelength results of FIG. 4G are plotted in FIG. 4H. Moreover, the structural colors for both FIG. 4F and FIG. 4H are displayed in FIG. 4I as CIE coordinates.

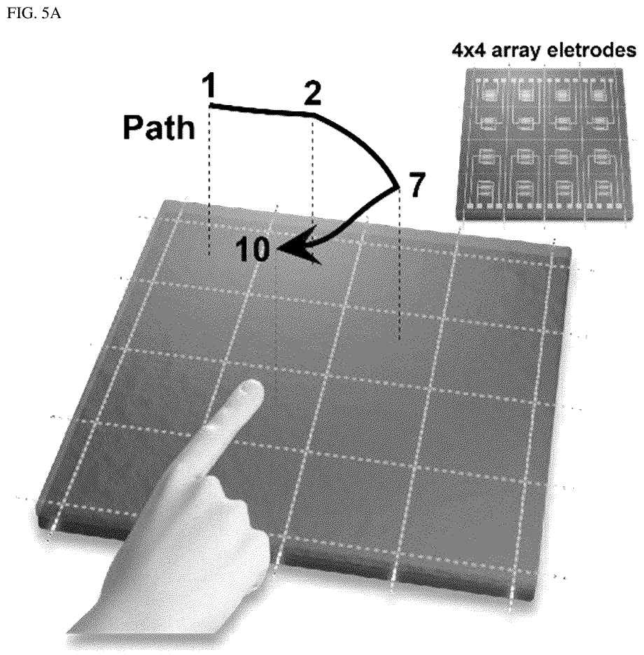

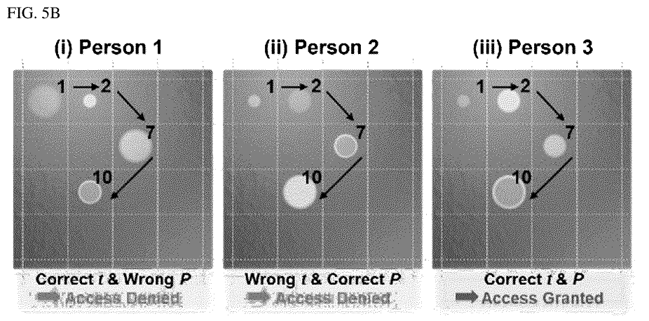

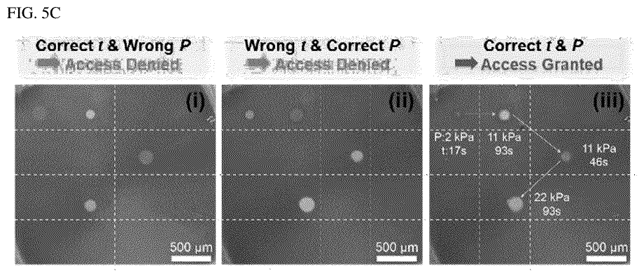

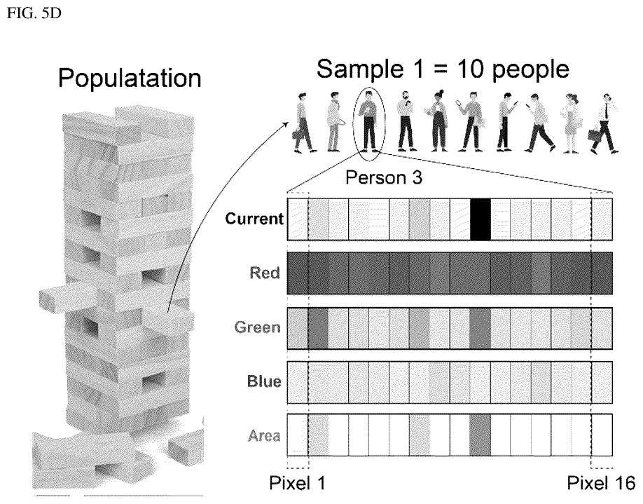

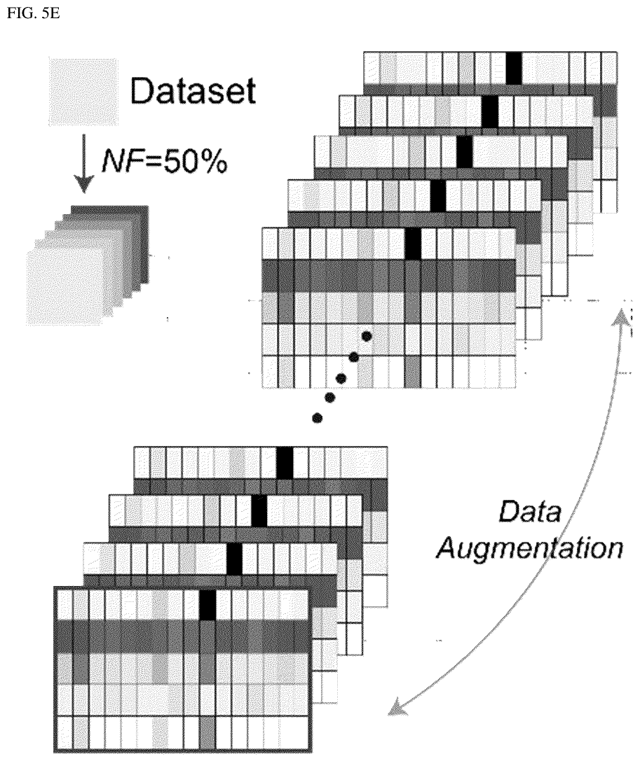

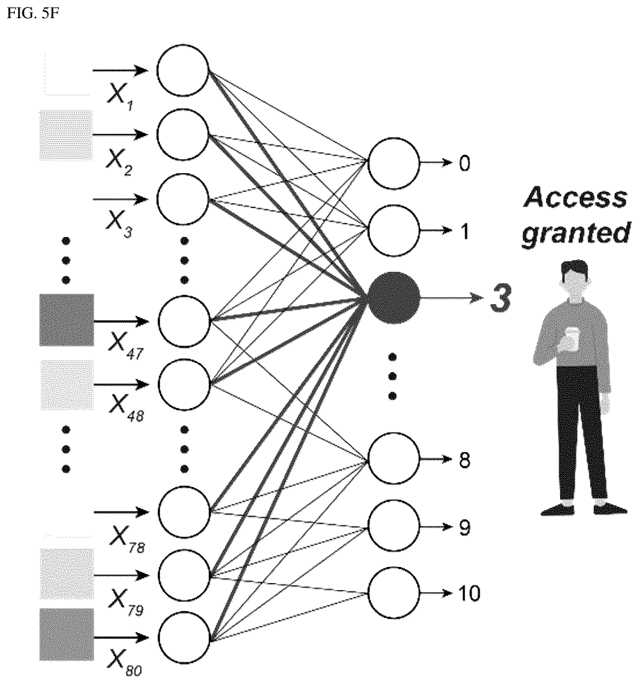

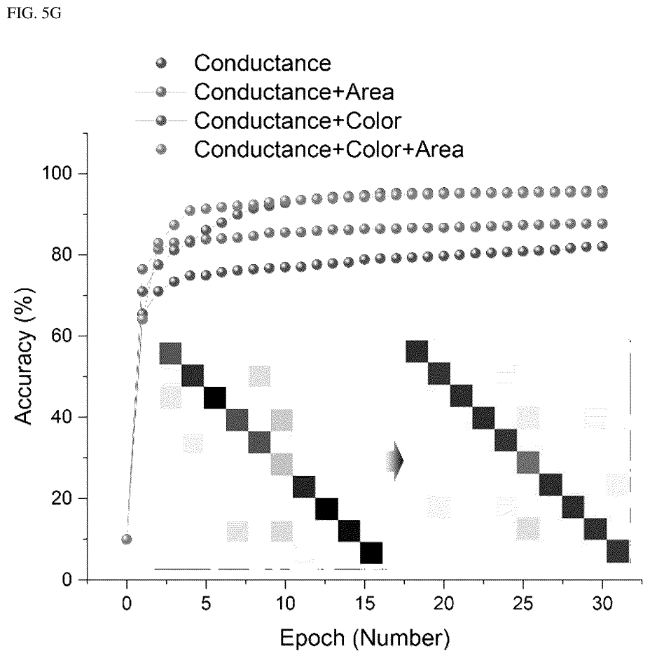

The inventors of the present disclosure fabricated a 4×4 array of TNSCD to propose a novel triple-mode personalized locking device capable of detecting and learning individual pressing information through the magnitude of pressure, wavelength, and current parameters. Unlike conventional commercial locking systems that can be bypassed if the pattern route is known regardless of the magnitude of pressure, the present newly developed locks offer enhanced security. This is achieved by capitalizing on variations in pressing time and magnitude, unique to each individual. Even if the pattern route is known, unauthorized access is hindered due to the requirement for distinct pressing time and pressure combinations tailored to each user. The array was constructed in a 4×4 interdigitated electrode pattern, which is schematically illustrated in FIG. 5A. The inventors of the present disclosure conducted an experiment by setting a path that presses pixels 1, 2, 7, and 10 out of 16 pixels. All pixels are initially red-colored immediately after creation. Even when the pressure is exerted following the designated path and the timing aligns with the correct answer, deviations in pressure magnitudes lead to incongruences, as shown in FIG. 5B-(i). Likewise, deviations in pressing time result in denied access even though the path and pressure magnitude are correct, as shown in FIG. 5B-(ii). These discrepancies become evident in the mismatch between the SC and the associated area, as demonstrated in FIG. 5C-(i), (ii). Furthermore, it's worth noting that the postsynaptic current between the source and drain electrodes also diverges from the anticipated response. As the time or magnitude of applied pressure varies, the postsynaptic current, after the pressing process is done, is also different from the correct answer in this case; thereby, access is denied. The access is allowed only if both the time to apply pressure and the pressure to each pixel match the correct answer, as shown in FIG. 5B-(iii) and FIG. 5C-(iii).

To comprehensively evaluate the learning capability of the present personalized locking device, the inventors of the present disclosure conducted the recognition simulations of individual unlocking patterns with three different parameters: post-synaptic current, structural color, and the area of pressure applied. Note that the inventors of the present disclosure established boundaries within similar patterns by utilizing three distinct pressures, specifically 2.35 kPa, 11.08 kPa, and 21.97 kPa. Additionally, the inventors of the present disclosure employed three different durations of pressure application, namely 15 s, 45 s, and 95 s, to ensure accurate and consistent pattern recognition even in potentially ambiguous scenarios. Therefore, the total number of cases in this system is determined by the product of all combinations across the designated pixels: 9 (pixel 1)×9 (pixel 2)×9 (pixel 7)×9 (pixel 10), which totals 6,561. In other words, if the system can accurately discern the correct pattern from these 6,561 analogous cases through adept learning processes, the access will be granted exclusively to the authorized individual. The alteration of SC is intricately linked to the processes of ion diffusion and the movement facilitated by electric fields, resulting in a relatively prolonged timescale for achieving the desired outcomes, which limits its practical applications. However, this challenge can be addressed by employing a patterning technique on the block copolymer (BCP) layer, which can significantly accelerate the diffusion process.

To enhance the reliability of the learning process, the inventors of the present disclosure treated the 6,561 cases as a population pool. From this pool, the inventors of the present disclosure randomly extracted five sample sets, with each set containing ten distinct patterns, as shown in FIG. 5D. Each individual pattern within a sample set has encoded information on the post-synaptic current, SC characterized by RGB values (255, 255, 255), and the area where the pressure was applied, as illustrated in FIG. 5E. Consequently, every pixel embodies five unique information data. For the effective training of the artificial neural network, the inventors of the present disclosure generated 500 data sets for each individual data (class) within every sample set, 75% of which data were used for training and 25% were used for testing, respectively. This was achieved by integrating a noise factor (NF), wherein the data of each pixel was multiplied by a randomly generated number, capped at a maximum of 0.5 (or 50%). This methodology was adopted to account for potential variances or errors that could arise during individual pressing events.

A single-layer neural network with a sigmoid activation function was employed as a classifier for the ten different unlocking patterns that were encoded on the 4×4 TNSCD array, as shown in FIG. 5G. The 80 (16×5) pixelated data sets of each pattern were individually connected to the pre-neurons (X1, X2, . . . , and X80) in order. The post-neurons (Y1, Y2, . . . , Y10) were assigned to ten different unlocking patterns, representing different individuals, from person 1 to person 10. The backpropagation learning algorithm and the fitting parameters were selected to be fitted well with the LTP and LTD functions of TNSCD. FIG. 5H shows the averaged recognition accuracy results derived from the five extracted samples, plotted as a function of learning epochs. The three distinct parameters of conductance, structural color, and the area pressure applied were used with different combinations. The accuracy results show that the recognition accuracy increased with incorporating a greater number of parameters. This implies that the present personalized locking system has enhanced security due to the specified input data.

Based on this simulation, the inventors of the present disclosure achieved about 96% accuracy at 30 epochs with conductance, color, and area data even with an NF value set at 50%. This computational achievement is visualized by the progression from an initially indistinct confusion matrix (shown on the left inset of FIG. 5G) to one that is predominantly diagonal, indicating a near-perfect alignment between target and output patterns (the presented in the right inset of FIG. 5G).

### Discussion

The inventors of the present disclosure have developed a novel Tactile Neuromorphic Structural Color Display (TNSCD), which was implemented on a single field-effect transistor synaptic platform. This device incorporated a gate dielectric made of a block copolymer (BCP) photonic crystal (PC) with Li⁺TFSI⁻ ions which were readily diffused within the BCP lamellae under the application of gate electric fields. The swelling and de-swelling of the lamellae depending upon the polarity of the electric field allowed the present device to exhibit reflective mode display through SC changes in full visible range. In addition, to enable pressure sensing, a dome-shaped gate electrode was introduced that acts as a pressure receptor and converter, translating pressure into electric voltage. This pressure receptor rendered the present device exhibit diverse synaptic properties according to external pressures, including paired-pulse facilitation and long-term potentiation. Moreover, the TNSCD displayed different structural colors depending on the magnitude and repetition of external pressures. In addition to its tactile-visualization capabilities, the inventors of the present disclosure demonstrated a novel high security triple-mode personalized locking platform in which the arrays of TNSCDs detected and learned individual unlocking information through the magnitude of pressure, wavelength, and drain current. This breakthrough opens up possibilities for wearable smart interactive displays and personal information encryption.

### Materials and Methods

### Materials

PS-b-P2VP was synthesized via living anionic polymerization. The average molecular weight (Mn) of the PS-b-P2VP was 125 kg mol-1, and the dispersity (Ð=Mw/Mn) was less than 1.04, as characterized by size-exclusion chromatography. The PS volume fraction (ƒPS) of BCP was determined to be 0.49 by 1H NMR. PGMEA, chloroform, Li⁺TFSI⁻, bromoethane, 1,4-dibromobutane, n-hexane, acetonitrile, toluene, DI water, P3HT (Mw=180,000 g mol-1) with 98.5% head-to-tail regioregularity, and polyvinylalcohol (PVA) were purchased from Sigma-Aldrich. PVDF-TrFE-CFE was purchased from PIEZOTECH. PDMS (Sylgard 184) and crosslinkers were purchased from Dow Corning.

### Preparation of BCP PC Film

A PVA solution in DI water (3 wt %) was spin coated on UVO treated Si substrate. Then, BCP PC films were fabricated by spin coating a 7 wt % PS-b-P2VP solution in PGMEA. The films were then solvent-annealed in chloroform vapor at 60° C. for 24 h. Subsequently, the P2VP domains were selectively quaternized with 1-bromoethane and 1,4-dibromobutane in n-haxane at 60° C. for 15 h. The initial SC of the BCP PC film was controlled by the degree of crosslinking with the 1,4-dibromobutane during quaternization.

### Fabrication of 2-Termnal E-Switching BCP SC Display

The Cr/Au bottom electrodes with thicknesses of 2 nm and 30 nm, respectively, were deposited onto a glass substrate through thermal evaporation with a metal mask. A P3HT solution in toluene (1 wt %) was spin-coated on a patterned electrode at 2000 rpm for 60 s. The P3HT film was heat-treated at 135° C. for 20 minutes to enhance the electrical properties of P3HT. Then, the prepared BCP PC film was transferred by floating on DI water. Subsequently, an ionic polymer blend (PVDF-TrFE-CFE:Li+TFSI−) was prepared by adding Li+TFSI− salt to a 10 wt % PVDF-TrFE-CFE solution in acetonitrile. The blend was then spin-coated on the BCP PC film by spin-coating at 2000 rpm for 60 s. The top Au electrodes with a thickness of 70 nm were deposited through thermal evaporation using a metal mask.

### Fabrication of Tactile Neuromorphic Structural Color Display

Fabrication of TNSCD except the pressure-sensitive gate electrode is same with that of 2-terminal E-switching BCP SC display. The pressure sensitive dome-shaped gate electrode was prepared by following procedure. PDMS (pre-polymer and curing agent ratio of 10:1) was poured onto a dome-shaped Si mold and subsequently annealed at 80° C. for 12 h to harden it. The Au electrodes with a thickness of 100 nm were deposited through thermal evaporation onto the PDMS.

### Device Characterization

The nanostructures of the BCP film and BCP PC/IG bilayer films were characterized using transmission mode of SAXS using the PLS-II 9A U-SAXS beamline at the Pohang Accelerator Laboratory. The cross-section of the Tactile Neuromorphic Structural Color Display was examined using a focused ion beam scanning electron microscopy (FIB-SEM) (JIB-4610F, JEOL, and Helios 5 US, FEI). Cyclovoltammetry was performed with a 50 mV/s scan using a multichannel potentiostat (VMP2, Biologic). The wavelength of the BCP PC/IG bilayer from the 50 cycles of on/off E-switching examination was calculated by extracting the CIE x and y coordinates, followed by conversion to red, green, blue (RGB), and hue, saturation, lightness (HSL) coordinates. The hue value was then converted to wavelength using the following equation: Wavelength=650−(250/270)×Hue. Transistor properties and synaptic characteristics measurements were determined using a Keithley 4200 semiconductor characterization system and a semiconductor parameter analyzer (4155C, Keysight) equipped with a pulse generator (81104A, Keysight). Pressure was applied and measured using z-axis pressure equipment combined with force gauges.

### Single Neural Network Simulation for Pattern Recognition

Single-layer neural network simulations based on TNSCD were performed using the array dataset composed of post-synaptic current, structural color characterized by RGB values (255, 255, 255), and the area where the pressure was applied. Array datasets were augmented by multiplying the noise factor (NF) with the original array dataset. The augmented datasets were divided by training datasets and test datasets at a ratio of 75:25. The inventors of the present disclosure developed an algorithm for simulation using the Python language. Based on the supervised learning, the weights were repeatedly updated using the stochastic gradient ascent/descent algorithm.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. A pressure-sensitive transistor device comprising:
a semiconductor layer;
a block copolymer layer disposed on an upper surface of the semiconductor layer, wherein the block copolymer layer has a stack structure in which hydrophilic layers and hydrophobic layers are vertically and alternately stacked on top of each other, wherein the block copolymer layer contains cations and anions therein;
an ion-gel layer disposed on an upper surface of the block copolymer layer;
a source electrode and a drain electrode disposed on a lower surface of the semiconductor layer and electrically contacting the semiconductor layer, wherein the source electrode and the drain electrode area spaced apart from each other; and
a gate electrode disposed on an upper surface of the ion-gel layer and in electrical and physical contact with the ion-gel layer.

2. The pressure-sensitive transistor device of claim 1, wherein each of the hydrophobic layers includes polystyrene (PS).

3. The pressure-sensitive transistor device of claim 1, wherein each of the hydrophilic layer includes quaternized poly(2-vinylpyridine) (QP2VP).

4. The pressure-sensitive transistor device of claim 1, wherein the cation is a lithium (Li) cation, or the anion is a trifluoromethanesulfonyl imide (TFSI) anion.

5. The pressure-sensitive transistor device of claim 1, wherein the semiconductor layer includes poly(3-hexylthiophene-2,5-diyl) (P3HT).

6. The pressure-sensitive transistor device of claim 1, wherein the ion-gel layer includes a polymer selected from polyvinylidene fluoride (PVDF), trifluoroethylene (TrFE), and chlorofluoroethylene (CFE),
wherein the ion-gel layer contains the cation and the anion therein.

7. The pressure-sensitive transistor device of claim 1, wherein each of the source electrode, the drain electrode and the gate electrode includes gold (Au).

8. The pressure-sensitive transistor device of claim 1, wherein the gate electrode has a dome shape convex toward the ion-gel layer.

9. The pressure-sensitive transistor device of claim 1, wherein the gate electrode is constructed to transfer a vertical pressure to the ion-gel layer and to the block copolymer layer.

10. The pressure-sensitive transistor device of claim 9, wherein the pressure-sensitive transistor device is configured such that when both a pressure and a voltage are simultaneously applied to the gate electrode, a structural color of the block copolymer layer changes.

11. The pressure-sensitive transistor device of claim 1, wherein the pressure-sensitive transistor device is configured such that when a pressure is applied to the gate electrode or a voltage is applied to the gate electrode, an electrical conductivity between the source electrode and the drain electrode through the semiconductor layer changes.

12. A pressure-sensitive transistor display comprising:
a plurality of pressure-sensitive transistor devices arranged in an array,
wherein the plurality of pressure-sensitive transistor devices have pressure receiving surfaces, wherein the have pressure receiving surfaces are arranged so as to be aligned with each other,
wherein each of at least some of the plurality of pressure-sensitive transistor devices includes the pressure-sensitive transistor device of claim 1.

13. The pressure-sensitive transistor display of claim 12, wherein the pressure-sensitive transistor device is configured such that when both a pressure and a voltage are simultaneously applied to the gate electrode, a structural color of the block copolymer layer changes.

14. The tactile input pattern recognition system comprising:
the pressure-sensitive transistor display of claim 12; and
a computing means configured to:
receive an electrical signal and a color signal from each of the pressure-sensitive transistor devices included in the pressure-sensitive transistor display, wherein the electrical signal and the color signal are based on an actual input pattern to the pressure-sensitive transistor display; and
derive a similarity between the actual input pattern and a predetermined input pattern, based on the received electrical signal and color signal.

15. The tactile input pattern recognition system of claim 14, wherein the computation means is pre-trained in a deep learning manner.
